(19) United States
(12) Patent Application Publication
(10) Pub. No.: US 2026/0148792 A1
(43) Pub. Date: May 28, 2026

(54) MEMORY DEVICES FOR PROVIDING CHIP-KILL

(71) Applicant: SK hynix Inc., Icheon-si Gyeonggi-do (KR)

(72) Inventors: Jong Sam KIM, Icheon-si Gyeonggi-do (KR); Sun Myung CHOI, Icheon-si Gyeonggi-do (KR)

(73) Assignee: SK hynix Inc., Icheon-si Gyeonggi-do (KR)

(21) Appl. No.: 19/053,185

(22) Filed: Feb. 13, 2025

(30) Foreign Application Priority Data
Nov. 26, 2024 (KR) 10-2024-0171537

(51) Int. Cl. G11C 29/38; H01L 25/065; H10B 80/00

(52) U.S. Cl. CPC G11C 29/38; H10B 80/00; H10W 90/00; H10W 90/297

(57) ABSTRACT

A memory device includes a plurality of stacked slice chips. The plurality of slice chips are electrically connected to each other through a plurality of through-vias, and when one of the plurality of slice chips is chip-killed, the operation of the plurality of slice chips is determined by correcting a slice ID in each of the plurality of slice chips. In addition, among the slice chips that are not chip-killed among the plurality of slice chips, a slice chip at a lowest layer and a slice chip at a highest layer are determined to operate.

### CROSS-REFERENCE TO RELATED APPLICATIONS

The present application claims priority under 35 U.S.C § 119(a) to Korean Application No. 10-2024-0171537, filed in the Korean Intellectual Property Office on Nov. 26, 2024, the entire contents of which application is incorporated herein by reference.

### BACKGROUND

### 1. Technical Field

Some embodiments of the present disclosure relate to memory devices that provide chip-kill.

### 2. Related Art

Recently, stack memory systems, such as high bandwidth memory (HBM) devices, have been used in a wide range of applications due to their excellent bandwidth and energy efficiency. Unlike conventional memory systems that use parallel data buses, the stack memory system includes a stack memory device including a base chip and a plurality of memory chips, which are interconnected by through silicon vias (TSVs). The stack memory device includes a physical interface, such as a physical layer for communication with a processor. The physical layer is designed for high-speed data transmission and efficient communication.

Memory devices can correct and recover errors contained in data. Technologies for correcting and recovering errors include a technology for correcting bit-level errors using error-correcting codes (ECC) and Chip Kill that provides a more powerful error-correcting function that can recover data even when a memory chip itself fails.

### SUMMARY

The present disclosure may provide a memory device including a plurality of stacked slice chips. The plurality of slice chips may be electrically connected to each other through a plurality of through-vias, and when one of the plurality of slice chips is chip-killed, an operation of the plurality of slice chips is determined by correcting a slice ID in each of the plurality of slice chips. In addition, among the slice chips that are not chip-killed among the plurality of slice chips, a slice chip at a lowest layer and a slice chip at a highest layer may be determined to operate.

In addition, the present disclosure may provide a memory device including a first slice chip, a second slice chip is stacked over a first slice chip, a third slice chip is stacked over the second slice chip, and a fourth slice chip is stacked over the third slice chip. When the second slice chip is chip-killed, the first slice chip and the fourth slice chip may be configured to operate and the second slice chip and the third slice chip may be configured to stop operating.

### BRIEF DESCRIPTION OF THE DRAWINGS

FIG. 1 illustrates a memory device according to an embodiment of the present disclosure.

FIG. 2 illustrates an embodiment of a first slice chip included in a memory device.

FIG. 3 illustrates an embodiment of a slice ID calibration circuit included in a first slice chip.

FIG. 4 illustrates an embodiment of a corrected slice ID generation circuit included in a slice ID calibration circuit.

FIG. 5 is a table identifying signals transferred during an operation that generates a first slice ID in a first slice chip.

FIG. 6 is a table identifying signals transferred during an operation that generates a first inverted signal in a slice ID calibration circuit.

FIG. 7 is a table identifying signals transferred during an operation that generates a first corrected slice ID in a first corrected slice ID generation circuit.

FIG. 8 illustrates an embodiment of a second slice chip included in a memory device.

FIG. 9 illustrates an embodiment of a slice ID calibration circuit included in a second slice chip.

FIG. 10 illustrates an embodiment of a corrected slice ID generation circuit included in a slice ID calibration circuit.

FIG. 11 is a table identifying signals transferred during an operation that generates a second slice ID in a second slice chip.

FIG. 12 is a table identifying signals transferred during an operation that generates a second inverted signal in a slice ID calibration circuit.

FIG. 13 is a table identifying signals transferred during an operation that generates a second corrected slice ID in a second corrected slice ID generation circuit.

FIG. 14 illustrates an embodiment of a third slice chip included in a memory device.

FIG. 15 illustrates an embodiment of a slice ID calibration circuit included a third slice chip.

FIG. 16 illustrates an embodiment of a corrected slice ID generation circuit included in a slice ID calibration circuit.

FIG. 17 is a table identifying signals transferred during an operation that generates a third slice ID in a third slice chip.

FIG. 18 is a table identifying signals transferred during an operation that generates a third inverted signal in a slice ID calibration circuit.

FIG. 19 is a table identifying signals transferred during an operation that generates a third corrected slice ID in a third corrected slice ID generation circuit.

FIG. 20 illustrates an embodiment of a fourth slice chip included in a memory device.

FIG. 21 illustrates an embodiment of a slice ID calibration circuit included in a fourth slice chip.

FIG. 22 illustrates an embodiment of a corrected slice ID generation circuit included in a slice ID calibration circuit.

FIG. 23 is a table identifying signals transferred during an operation that generates a fourth slice ID in a fourth slice chip.

FIG. 24 is a table identifying signals transferred during an operation that generates a fourth inverted signal in a slice ID calibration circuit.

FIG. 25 is a table identifying signals transferred during an operation that generates a fourth corrected slice ID in a fourth corrected slice ID generation circuit.

FIG. 26 to FIG. 28 illustrate a memory device in which an operation that generates corrected slice IDs from slice IDs is performed when chip-kill occurs in each of the slice chips included in a memory device.

FIG. 29 is a block diagram illustrating a stack memory system according to an embodiment of the present disclosure.

FIG. 30 is a block diagram illustrating a stack memory system according to another embodiment of the present disclosure.

### DETAILED DESCRIPTION

In the following description of embodiments, when a parameter is referred to as being “predetermined,” a value of the parameter may be determined in advance when the parameter is used in a process or an algorithm. The value of the parameter may be determined when the process or the algorithm starts or may be determined during a period in which the process or the algorithm is executed.

Although the terms “first,” “second,” “third,” and so forth are used herein to describe various elements, these elements should not be limited by these terms. These terms are only used to distinguish one element from another element and are not intended to imply an order or number of elements. Thus, a first element in some embodiments may be termed a second element in other embodiments without departing from the teachings of the present disclosure.

When an element is referred to as “connected” or “coupled” to another element, the element may be directly connected or coupled to the other element or intervening elements may be present. When an element is referred to as “directly connected” or “directly coupled” to another element, no intervening elements are present.

A logic “high” level and a logic “low” level may be used to describe logic levels of electric signals. A signal at a logic “high” level is distinguished from a signal at a logic “low” level. For example, when a signal at a first voltage corresponds to a signal at a logic “high” level, a signal at a second voltage corresponds to a signal at a logic “low” level. In an embodiment, the logic “high” level may be a voltage level that is higher than a voltage level of the logic “low” level. Logic levels of signals may be different or opposite according to the embodiments. For example, a certain signal at a logic “high” level in one embodiment may be at a logic “low” level in another embodiment, and a certain signal at a logic “low” level in one embodiment may be at a logic “high” level in another embodiment.

Various embodiments of the present disclosure are described in more detail with reference to the accompanying drawings. The embodiments are described for illustrative purposes only and are not intended to limit the scope of the present disclosure.

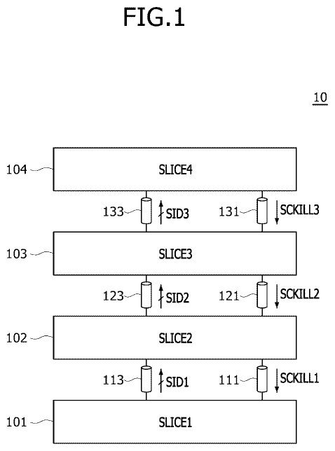

FIG. 1 illustrates a memory device 10 according to an embodiment of the present disclosure.

As shown in FIG. 1, the memory device 10 includes a first slice chip 101, a second slice chip 102, a third slice chip 103, and a fourth slice chip 104. The first slice chip 101 and the second slice chip 102 are electrically connected to each other through a first though-via 111 and a second through-via 113. The second slice chip 102 and the third slice chip 103 are electrically connected to each other through a third though-via 121 and a fourth through-via 123. The third slice chip 103 and the fourth slice chip 104 are electrically connected to each other through a fifth though-via 131 and a sixth through-via 133.

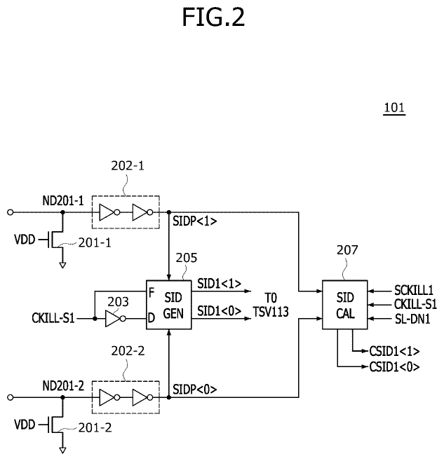

The first slice chip 101 receives a first synthetic chip kill signal SCKILL1 through the first through-via 111. The first synthetic chip kill signal SCKILL1 is activated when one of the second slice chip 102, the third slice chip 103, and the fourth slice chip 104 is chip-killed. The first slice chip 101 may be designated as a master chip that controls the operations of slave chips including the second slice chip 102, the third slice chip 103, and the fourth slice chip 104. The first slice chip 101 may be configured to not be chip-killed. The first slice chip 101 is configured to generate a first slice ID SID1 having a preset binary bit set. For example, the first slice chip 101 may be configured to generate the first slice ID SID1<1:0> having a binary bit set of “01”. The first slice chip 101 transmits the first slice ID SID1 to the second slice chip 102 through the second through-via 113. The first slice chip 101 is configured to generate a first corrected slice ID(For example, CSID1<1:0> in FIG. 2) having a preset binary bit set. For example, the first slice chip 101 may be configured to generate the first corrected slice ID having a binary bit set of “00”. The first slice chip 101 is configured to operate regardless of whether one of the second slice chip 102, the third slice chip 103, and the fourth slice chip 104 is chip-killed.

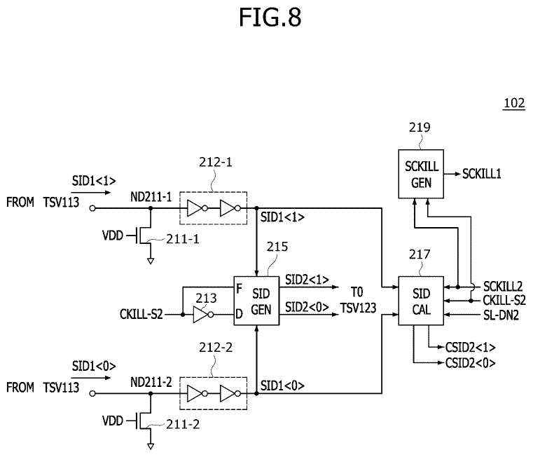

The second slice chip 102 receives a second synthetic chip kill signal SCKILL2 through the third through-via 121. The second synthetic chip kill signal SCKILL2 is activated when one of the third slice chip 103 and the fourth slice chip 104 is chip-killed. The second slice chip 102 may be designated as a slave chip that operates under the control of the first slice chip 101 designated as the master chip. The second slice chip 102 up-counts the bit set of the first slice ID SID1 to output a second slice ID SID2 when the second slice chip 102 is not chip-killed. For example, when the first slice ID SID1<1:0> having a binary bit set of “01” is received while the second slice chip 102 is not chip-killed, the second slice chip 102 may up-count the binary bit set of “01” of the first slice ID SID1<1:0> by one bit to generate the second slice ID SID2<1:0> having a binary bit set of “10”. The second slice chip 102 outputs the first slice ID SID1 as the second slice ID SID2 when the second slice chip 102 is chip-killed. For example, when the first slice ID SID1<1:0> having a binary bit set of “01” is received while the second slice chip 102 is chip-killed, the second slice chip 102 may generate the second slice ID SID2<1:0> having the same binary bit set of “01” as the first slice ID SID1. The second slice chip 102 transmits the second slice ID SID2 to the third slice chip 103 through the fourth through-via 123. The second slice chip 102 is set to generate a second corrected slice ID(For example, CSID2<1:0> in FIG. 8) having a preset binary bit set when the second slice chip 102 is chip-killed. For example, the second slice chip 102 may generate the second corrected slice ID having a preset binary bit set of “11” when the second slice chip 102 is chip-killed. When one of the third slice chip 103 and the fourth slice chip 104 is chip-killed, the second slice chip 102 is set to generate the second corrected slice ID having a preset binary bit set. For example, when one of the third slice chip 103 and the fourth slice chip 104 is chip-killed, the second slice chip 102 may generate the second corrected slice ID having a preset binary bit set of “10”. The second slice chip 102 is set to stop operating when one of the second slice chip 102, the third slice chip 103, and the fourth slice chip 104 is chip-killed.

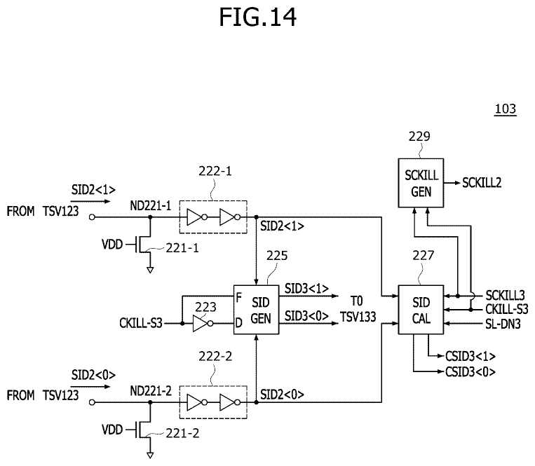

The third slice chip 103 receives a third synthetic chip kill signal SCKILL3 through the fifth through-via 131. The third synthetic chip kill signal SCKILL3 is activated when the fourth slice chip 104 is chip-killed. The third slice chip 103 may be designated as a slave chip that operates under the control of the first slice chip 101 designated as the master chip. The third slice chip 103 up-counts the bit set of the second slice ID SID2 to output a third slice ID SID3 when the third slice chip 103 is not chip-killed. For example, when the second slice ID SID2<1:0> having a binary bit set of “10” is received while the third slice chip 103 is not chip-killed, the third slice chip 103 may up-count the binary bit set of the second slice ID SID2<1:0> by one bit to generate the third slice ID SID3<1:0> having a binary bit set of “11”. The third slice chip 103 outputs the second slice ID SID2 as the third slice ID SID3 when the third slice chip 103 is chip-killed. For example, when the second slice ID SID2<1:0> having a binary bit set of “10” is received while the third slice chip 103 is chip-killed, the third slice chip 103 may generate the third slice ID SID3<1:0> having the same binary bit set of “10” as the second slice ID SID2. The third slice chip 103 transmits the third slice ID SID3 to the fourth slice chip 104 through the sixth through-via 133. The third slice chip 103 is set to generate a third corrected slice ID(For example, CSID3<1:0> in FIG. 14) having a preset binary bit set when the third slice chip 103 is chip-killed. For example, the third slice chip 103 may generate the third corrected slice ID having a preset binary bit set of “11” when the third slice chip 103 is chip-killed. When one of the second slice chip 102 and the fourth slice chip 104 is chip-killed, the third slice chip 103 is set to generate the third corrected slice ID having a preset binary bit set. For example, the third slice chip 103 may generate the third corrected slice ID having a preset binary bit set of “10” when the second slice chip 102 is chip-killed and may generate the third corrected slice ID having a preset binary bit set of “01” when the fourth slice chip 104 is chip-killed. The third slice chip 103 is set to stop operating based on the third corrected slice ID when one of the second slice chip 102 and the third slice chip 103 is chip-killed. The third slice chip 103 is set to operate when the fourth slice chip 104 is chip-killed.

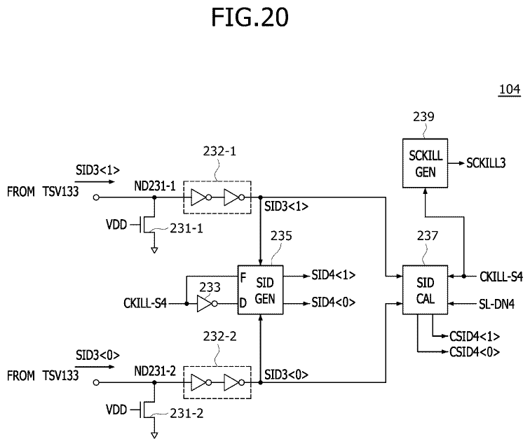

The fourth slice chip 104 may be designated as a slave chip that operates under the control of the first slice chip 101 designated as the master chip. The fourth slice chip 104 up-counts the bit set of the third slice ID SID3 to output a fourth slice ID SID4 when the fourth slice chip 104 is not chip-killed. For example, when the third slice ID SID3<1:0> having a binary bit set of “11” is received while the fourth slice chip 104 is not chip-killed, the fourth slice chip 104 may up-count the binary bit set of the third slice ID SID3<1:0> by one bit to generate the fourth slice ID SID4<1:0> having a binary bit set of “00”. The fourth slice chip 104 outputs the third slice ID SID3 as the fourth slice ID SID4 when the fourth slice chip 104 is chip-killed. For example, when the third slice ID SID3<1:0> having the binary bit set of “11” is received while the fourth slice chip 104 is chip-killed, the fourth slice chip 104 may generate the fourth slice ID SID4<1:0> having the same binary bit set of “11” as the third slice ID SID3. The fourth slice chip 104 is set to generate a fourth corrected slice ID(For example, CSID4<1:0> in FIG. 20) having a preset binary bit set when the fourth slice chip 104 is chip-killed. For example, the fourth slice chip 104 may generate the fourth corrected slice ID having a preset binary bit set of “11” when the fourth slice chip 104 is chip-killed. When the fourth slice chip 104 is chip-killed and the fourth corrected slice ID having the binary bit set of “11”, the fourth slice chip 104 is set to stop operating. The fourth slice chip 104 is set to generate the fourth corrected slice ID having the preset binary bit set when one of the second slice chip 102 and the third slice chip 103 is chip-killed. For example, when one of the second slice chip 102 and the third slice chip 103 is chip-killed, the fourth slice chip 104 may generate the fourth corrected slice ID having a preset binary bit set of “01”. When one of the second slice chip 102 and the third slice chip 103 is chip-killed and the fourth corrected slice ID having the binary bit set of “01”, the fourth slice chip 104 is set to operate.

FIG. 2 illustrates an embodiment of the first slice chip 101 included in a memory device according to the present disclosure, for example, as shown in FIG. 1.

As shown in FIG. 2, the first slice chip 101 includes NMOS transistors 201-1 and 201-2, buffers 202-1 and 202-2, an inverter 203, a slice ID generation circuit (SID GEN) 205, and a slice ID calibration circuit (SID CAL) 207.

The NMOS transistor 201-1 operates as a driving device that drives a node nd201-1 to a logic “low” level. The NMOS transistor 201-2 operates as a driving device that drives a node nd201-2 to a logic “low” level. The node nd201-1 and the node nd201-2 may be initialized at a logic “low” level.

The buffer 202-1 buffers a signal of the node nd201-1 to generate a second bit SIDP<1> of a pre-slice ID. The buffer 202-2 buffers a signal of the node nd201-2 to generate a first bit SIDP<0> of the pre-slice ID. The pre-slice ID SIDP<1:0> is set and initialized to have a binary bit set of “00” by the buffers 202-1 and 202-2. The pre-slice ID SIDP<1:0> that is set to have the binary bit set of “00” means that both the second bit SIDP<1> of the pre-slice ID and the first bit SIDP<0> of the pre-slice ID are set at a logic “low” level.

The slice ID generation circuit 205 receives the pre-slice ID SIDP<1:0> through the buffers 202-1 and 202-2 that are electrically connected to the slice ID generation circuit 205. The slice ID generation circuit 205 receives a first chip kill signal CKILL-S1 through a first input terminal F and receives an inverted signal of the first chip kill signal CKILL-S1, inverted by the inverter 203, through a second input terminal D. The first chip kill signal CKILL-S1 is activated when the first slice chip 101 is chip-killed. The slice ID generation circuit 205 generates the first slice ID SID1<1:0> from the pre-slice ID SIDP<1:0> based on the first chip kill signal CKILL-S1 to generate the first slice ID SID1<1:0> through a second through-via 113 of FIG. 1. When the first slice chip 101 is not chip-killed and a deactivated first chip kill signal CKILL-S1 is received, the slice ID generation circuit 205 up-counts the pre-slice ID SIDP<1:0> to generate the first slice ID SID1<1:0>. For example, the slice ID generation circuit 205 may up-count the pre-slice ID SIDP<1:0>, which is set to have a binary bit set of “00”, by one bit to generate the first slice ID SID1<1:0> that is set to have a binary bit set of “01” when the deactivated first chip kill signal CKILL-S1 is received. When the first slice chip 101 is chip-killed and an activated first chip kill signal CKILL-S1 is received, the slice ID generation circuit 205 generates the first slice ID SID1<1:0> having a binary bit set that is the same as a binary bit set of the pre-slice ID SIDP<1:0>. For example, when the activated first chip kill signal CKILL-S1 is received, the slice ID generation circuit 205 may generate the first slice ID SID1<1:0>having the same binary bit set of “00” as the pre-slice ID SIDP<1:0>.

The slice ID calibration circuit 207 receives the pre-slice ID SIDP<1:0> through the buffers 202-1 and 202-2 that are electrically connected to the slice ID calibration circuit 207. The slice ID calibration circuit 207 generates a first corrected slice ID CSID1<1:0> from the pre-slice ID SIDP<1:0> based on the first synthetic chip kill signal SCKILL1, the first chip kill signal CKILL-S1, and a first down slice signal SL-DN1. Because the first down slice signal SL-DN1 is activated when the first slice chip 101 is at a lowest layer, the slice ID calibration circuit 207 receives the activated first down slice signal SL-DN1. When the activated first down-slice signal SL-DN1 is received, the slice ID calibration circuit 207 is set to generate the first corrected slice ID CSID1<1:0> having a preset binary bit set, regardless of the first synthetic chip kill signal SCKILL1 and the first chip kill signal CKILL-S1. For example, when the activated first down slice signal SL-DN1 is received, the slice ID calibration circuit 207 may be set to generate the first corrected slice ID CSID1<1:0> having the same binary bit set of “00” as the pre-slice ID SIDP<1:0>.

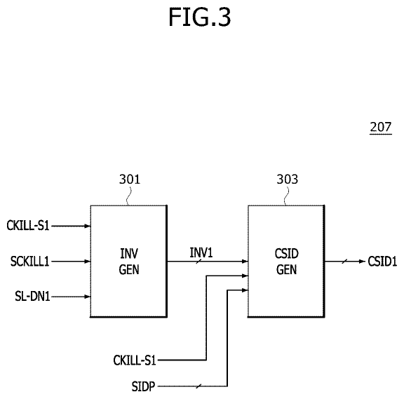

FIG. 3 illustrates an embodiment of a slice ID calibration circuit 207 included in a first slice chip, for example, as shown in FIG. 2.

As shown in FIG. 3, the slice ID calibration circuit 207 includes an inverted signal generation circuit (INV GEN) 301 and a corrected slice ID generation circuit (CSID GEN) 303.

The inverted signal generation circuit 301 generates a first inverted signal INV1 based on a first chip kill signal CKILL-S1, a first synthetic chip kill signal SCKILL1, and a first down slice signal SL-DN1. The first chip kill signal CKILL-S1 is deactivated to set the first slice chip 101 to not be chip-killed. The inverted signal generation circuit 301 receives an activated first down slice signal SL-DN1 to generate the first inverted signal INV1 that is deactivated regardless of the first synthetic chip kill signal SCKILL1 and the first chip kill signal CKILL-S1. Each bit included in the first inverted signal INV1 may be set to be deactivated at a logic “low” level; however, this is merely an example and the present disclosure is not limited thereto.

The corrected slice ID generation circuit 303 receives the first inverted signal INV1 from the inverted signal generation circuit 301 that is electrically connected to the corrected slice ID generation circuit 303. The corrected slice ID generation circuit 303 generates a first corrected slice ID SCID1 based on the first chip kill signal CKILL-S1 and the first inverted signal INV1. The corrected slice ID generation circuit 303 receives the first chip kill signal CKILL-S1 and the first inverted signal INV1, which are both deactivated, to generate the first corrected slice ID CSID1 that is set to have the same binary bit set as the pre-slice ID SIDP. For example, the corrected slice ID generation circuit 303 may generate the first corrected slice ID CSID1<1:0> having a binary bit set of “00”.

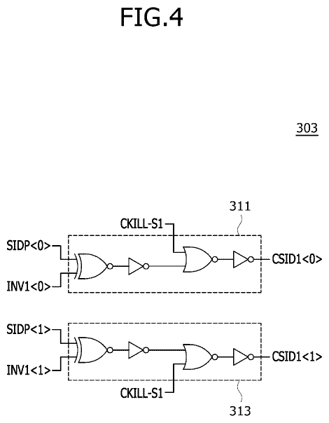

FIG. 4 illustrates an embodiment of a corrected slice ID generation circuit 303, for example, as shown in FIG. 3.

As shown in FIG. 4, the corrected slice ID generation circuit 303 includes a first corrected slice ID generation circuit 311 and a second corrected slice ID generation circuit 313.

The first corrected slice ID generation circuit 311 buffers a first bit SIDP<0> of a pre-slice ID according to a first chip kill signal CKILL-S1 and a first bit INV1<0> of an inverted signal INV1, which are deactivated at a logic “low” level, to generate a first bit CSID1<0> of the first corrected slice ID CSID1 at a logic “low” level.

The second corrected slice ID generation circuit 313 buffers a second bit SIDP<1> of the pre-slice ID according to the first chip kill signal CKILL-S1 and a second bit INV1<1> of the first inverted signal INV1, which are deactivated at a logic “low” level, to generate a second bit CSID1<1> of the first corrected slice ID CSID1 at a logic “low” level.

The corrected slice ID generation circuit 303 buffers the pre-slice ID SIDP<1:0> having a binary bit set of “00” according to the first chip kill signal CKILL-S1 and the first inverted signal INV1<1:0>, which are deactivated at a logic “low” level, to generate the first corrected slice ID CSID1<1:0> having a binary bit set of “00”.

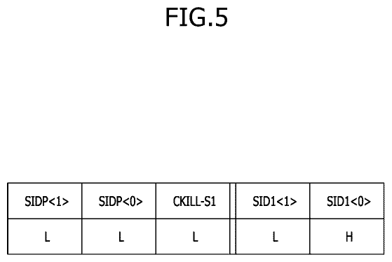

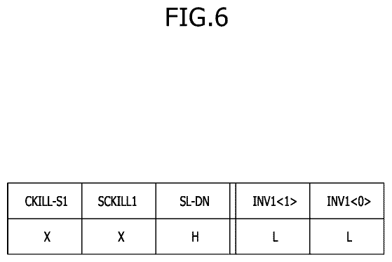

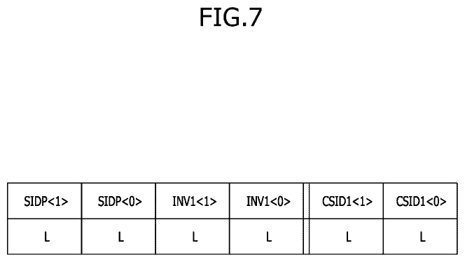

FIG. 5 is a table identifying signals transferred during an operation that generates a first slice ID SID1<1:0> in a first slice chip 101, such as shown in FIG. 2, FIG. 6 is a table identifying signals transferred during an operation that generates a first inverted signal INV1<1:0> in a slice ID calibration circuit 207, such as shown in FIG. 3, and FIG. 7 is a table identifying signals transferred during an operation that generates a first corrected slice ID CSID1<1:0> in the first slice chip 101, such as shown in FIG. 4.

Referring to FIG. 2 and FIG. 5, the slice ID generation circuit 205 of the first slice chip 101 up-counts the pre-slice ID SIDP<1:0>, which is set to have a binary bit set of “00” according to the first chip kill signal CKILL-S1 that is deactivated at a logic “low” level “L”, by one bit to generate the first slice ID SID1<1:0> that is set to have a binary bit set of “01”. The first slice ID SID1<1:0> being set to have the binary bit set of “01” means that the second bit SID1<1> of the first slice ID is set at a logic “low” level “L” and the first bit SID1<0> of the first slice ID is set at a logic “high” level “H”.

Referring to FIG. 3 and FIG. 6, the inverted signal generation circuit 301 of the slice ID calibration circuit 207 receives the first down slice signal SL-DN1 that is activated at a logic “high” level to generate the first inverted signal INV1<1:0> that is set to have a binary bit set of “00”, regardless of the first synthetic chip kill signal SCKILL1, the first chip kill signal CKILL1, and the pre-slice ID SIDP. The first inverted signal INV1<1:0> being set to have the binary bit set of “00” means that both the second bit INV1<1> of the first inverted signal and the first bit INV1<0> of the first inverted signal are set at a logic “low” level “L”.

Referring to FIG. 3, FIG. 4, and FIG. 7, the corrected slice ID generation circuit 303 generates the first corrected slice ID CSID1<1:0> having the same binary bit set of “00” as the pre-slice ID SIDP<1:0> according to the first chip kill signal CKILL-S1 deactivated at a logic “low” level “L” and the first inverted signal INV1<1:0> that is set to have a binary bit set of “00”. The first corrected slice ID CSID1 being set to have the binary bit set of “00” means that both the second bit CSID1<1> of the first corrected slice ID and the first bit CSID1<0> of the first corrected slice ID are set at a logic “low” level “L”.

FIG. 8 illustrates an embodiment of a second slice chip 102 included in the memory device according to the present disclosure, for example, as shown in FIG. 1.

As shown in FIG. 8, the second slice chip 102 includes NMOS transistors 211-1 and 211-2, buffers 212-1 and 212-2, an inverter 213, a slice ID generation circuit (SID GEN) 215, a slice ID calibration circuit (SID CAL) 217, and a synthetic chip kill signal generation circuit (SCKILL GEN) 219.

The NMOS transistor 211-1 operates as a driving device that drives a node nd211-1 to a logic “low” level. The NMOS transistor 211-2 operates as a driving device that drives a node nd211-2 to a logic “low” level. Both the node nd211-1 and the node nd211-2 may be initialized at a logic “low” level by the NMOS transistors 211-1 and 211-2. A logic level of the node nd211-1 may be set by a second bit SID1<1> of the first slice ID received through the second through-via 113 of FIG. 1. A logic level of the node nd211-2 may be set by a first bit SID1<0> of the first slice ID received through the second through-via 113.

The buffer 212-1 buffers a signal of the node nd211-1 to output the second bit SID1<1> of the first slice ID. The buffer 212-2 buffers a signal of the node nd 211-2 to output the first bit SID1<1:0> of the first slice ID. For example, the buffers 212-1 may buffer and output the first slice ID SID1<1:0> input with a binary bit set of “01”. The first slice ID SID1<1:0> being set to have the binary bit set of “01” means that the second bit SID1<1> of the first slice ID is set at a logic “low” level and the first bit SID1<0> of the first slice ID is set at a logic “high” level.

The slice ID generation circuit 215 receives the first slice ID SID1<1:0> through the buffers 212-1 and 212-2 that are electrically connected to the slice ID generation circuit 215. The slice ID generation circuit 215 receives the second chip kill signal CKILL-S2 through a first input terminal F and receives an inverted signal of the second chip kill signal CKILL-S2, inverted by the inverter 213, through a second input terminal D. The second chip kill signal CKILL-S2 is activated when the second slice chip 102 is chip-killed. The slice ID generation circuit 215 generates the second slice ID SID2<1:0> from the first slice ID SID1<1:0> based on the second chip kill signal CKILL-S2 and outputs the second slice ID SID2<1:0> through the fourth through-via 123 of FIG. 1. The slice ID generation circuit 215 up-counts the first slice ID SID1<1:0> to generate the second slice ID SID2<1:0> when the second slice chip 102 is not chip-killed and a deactivated second chip kill signal CKILL-S2 is received. For example, when the deactivated second chip kill signal CKILL-S2 is received, the slice ID generation circuit 215 may up-count the first slice ID SID1<1:0>, which is set to have a binary bit set of “01”, by one bit to generate the second slice ID SID2<1:0> that is set to have a binary bit set of “10”. The slice ID generation circuit 215 generates the second slice ID SID2<1:0> having the same binary bit set as the first slice ID SID1<1:0> when the second slice chip 102 is chip-killed and an activated second chip kill signal CKILL-S2 is received. For example, when the activated second chip kill signal CKILL-S2 is received, the slice ID generation circuit 215 may generate the second slice ID SID2<1:0> having the same binary bit set of “01” as the first slice ID SID1<1:0>.

The slice ID calibration circuit 217 receives the first slice ID SID1<1:0> through the buffers 212-1 and 212-2 that are electrically connected to the slice ID calibration circuit 217. The slice ID calibration circuit 217 generates a second corrected slice ID CSID2<1:0> from the first slice ID SID1<1:0> based on the second synthetic chip kill signal SCKILL2, the second chip kill signal CKILL-S2, and the second down slice signal SL-DN2. Because the second down slice signal SL-DN2 is activated when the second slice chip 102 is at a lowest layer, the slice ID calibration circuit 217 receives the deactivated second down slice signal SL-DN2. The slice ID calibration circuit 217 is set to generate the second corrected slice ID CSID2<1:0> having a binary bit set according to the second synthetic chip kill signal SCKILL2 and the second chip kill signal CKILL-S2 when the deactivated second down slice signal SL-DN2 is received. For example, when an activated second chip kill signal CKILL-S2 is received, the slice ID calibration circuit 217 may be set to generate the second corrected slice ID CSID2<1:0> having a binary bit set of “11”. The second corrected slice ID CSID2<1:0> being set to have the binary bit set of “11” means that both the second bit CSID2<1> of the second corrected slice ID and the first bit CSID2<0> of the second corrected slice ID are set at a logic “high” level. As another example, the slice ID calibration circuit 217 may be set to generate the second corrected slice ID CSID2<1:0> having a binary bit set of “10” when an activated second synthetic chip kill signal SCKILL2 is received. The second corrected slice ID CSID2<1:0> being set to have the binary bit set of “10” means that the second bit CSID2<1> of the second corrected slice ID is set at a logic “high” level and the first bit CSID2<0> of the second corrected slice ID is set at a logic “low” level.

The synthetic chip kill signal generation circuit 219 generates the first synthetic chip kill signal SCKILL1 based on the second synthetic chip kill signal SCKILL2 and the second chip kill signal CKILL-S2. The synthetic chip kill signal generation circuit 219 generates the first synthetic chip kill signal SCKILL1 that is activated when one of the second synthetic chip kill signal SCKILL2 and the second chip kill signal CKILL-S2 is activated. When the second slice chip 102 is chip-killed and an activated second chip kill signal CKILL-S2 is received or when one of the third slice chip 103 and the fourth slice chip 104 is chip-killed and an activated second synthetic chip kill signal SCKILL2 is received, the synthetic chip kill signal generation circuit 219 generates the first synthetic chip kill signal SCKILL1 that is activated. Accordingly, the synthetic chip kill signal generation circuit 219 generates the first synthetic chip kill signal SCKILL1 that is activated when one of the second slice chip 102, the third slice chip 103, and the fourth slice chip 104 is chip-killed.

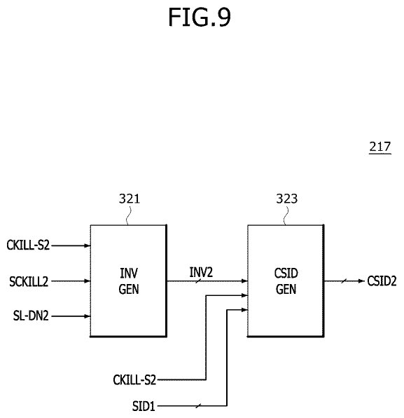

FIG. 9 illustrates an embodiment of a slice ID calculation circuit 217 included in a second slice chip, for example, as shown in FIG. 8.

As shown in FIG. 9, the slice ID calculation circuit 217 includes an inverted signal generation circuit (INV GEN) 321 and a corrected slice ID generation circuit (CSID GEN) 323.

The inverted signal generation circuit 321 generates a second inverted signal INV2 based on a second synthetic chip kill signal SCKILL2, a second chip kill signal CKILL-S2, and a second down slice signal SL-DN2. The inverted signal generation circuit 321 receives a deactivated second down slice signal SL-DN2 to generate the second inverted signal INV2 having a binary bit set that is set according to the second synthetic chip kill signal SCKILL2 and the second chip kill signal CKILL-S2. For example, the inverted signal generation circuit 321 may generate the second inverted signal INV2<1:0> that is set to have a binary bit set of “00” when the second synthetic chip kill signal SCKILL2 and the second chip kill signal CKILL-S2 that are both deactivated are received. As another example, the inverted signal generation circuit 321 may generate the second inverted signal INV2<1:0> that is set to have a binary bit set of a “don't care” state “X” when an activated second chip kill signal CKILL-S2 is received. The second inverted signal INV2<1:0> being set to have the binary bit set of the “don't care” state means that the binary bit set of the second inverted signal INV2<1:0> is generated to have one of the binary bit sets of “00”, “01”, “10”, and “11”. As another example, the inverted signal generation circuit 321 may generate the second inverted signal INV2<1:0> that is set to have a binary bit set of “11” when the activated second synthetic chip kill signal SCKILL2 is received.

The corrected slice ID generation circuit 323 receives the second inverted signal INV2 from the inverted signal generation circuit 321 that is electrically connected to the corrected slice ID generation circuit 323. The corrected slice ID generation circuit 323 generates a second corrected slice ID CSID2 according to a first slice ID SID1 based on the second chip kill signal CKILL-S2 and the second inverted signal INV2. The corrected slice ID generation circuit 323 receives the second chip kill signal CKILL-S2 and the second inverted signal INV2 that are both deactivated to generate the second corrected slice ID CSID2 set to have the same binary bit set as the first slice ID SID1. For example, the corrected slice ID generation circuit 323 may generate the second corrected slice ID CSID2 having a binary bit set of “01” when the first slice ID SID1 having a binary bit set of “01” is received. The corrected slice ID generation circuit 323 generates the second corrected slice ID CSID2 that is set to have a preset binary bit set when the activated second chip kill signal CKILL-S2 is received. For example, the corrected slice ID generation circuit 323 may generate the second corrected slice ID CSID2<1:0> having a binary bit set of “11” when the activated second chip kill signal CKILL-S2 is received. The corrected slice ID generation circuit 323 inverts the first slice ID SID1 to generate the second corrected slice ID CSID2 when the deactivated second chip kill signal CKILL-S2, the activated second synthetic chip kill signal SCKILL2, and the activated second inverted signal INV2 are received. For example, the corrected slice ID generation circuit 323 may invert the first slice ID SID1 having the binary bit set of “01” to generate the second corrected slice ID CSID2 having a binary bit set of “10” when the deactivated second chip kill signal CKILL-S2 and the activated second inverted signal INV2 are received.

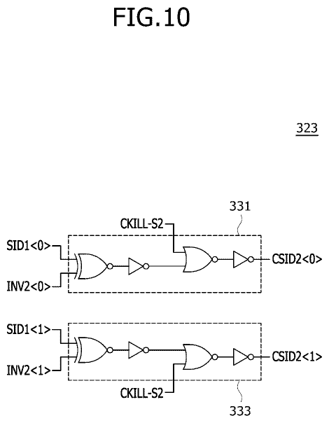

FIG. 10 illustrates an embodiment of a corrected slice ID generation circuit 323, for example, as shown in FIG. 9.

As shown in FIG. 10, the corrected slice ID generation circuit 323 includes a first corrected slice ID generation circuit 331 and a second corrected slice ID generation circuit 333.

The first corrected slice ID generation circuit 331 generates a first bit CSID2<0> of a second corrected slice ID that is set at a logic “high” level when a second chip kill signal CKILL-S2 that is activated at a logic “high” level is received. The first corrected slice ID generation circuit 331 buffers a first bit SID1<0> of a first slice ID to generate the first bit CSID2<0> of the second corrected slice ID according to the second chip kill signal CKILL-S2 and a first bit INV2<0> of a second inverted signal, which are all deactivated at a logic “low” level. The first corrected slice ID generation circuit 331 inversely buffers the first bit SID1<0> of the first slice ID to generate the first bit CSID2<0> of the second corrected slice ID according to the second chip kill signal CKILL-S2 that is deactivated at a logic “low” level and the first bit INV2<0> of the second inverted signal that is activated at a logic “high” level.

The second corrected slice ID generation circuit 333 generates a second bit CSID2<1> of the second corrected slice ID that is set at a logic “high” level when the second chip kill signal CKILL-S2 that is activated at a logic “high” level is received. The second corrected slice ID generation circuit 333 buffers a second bit SID1<1>of the first slice ID to generate a second bit CSID2<1> of the second corrected slice ID according to the second chip kill signal CKILL-S2 and a second bit INV2<1> of the second inverted signal that are all deactivated at a logic “low” level. The second corrected slice ID generation circuit 333 inversely buffers the second bit SID1<1> of the first slice ID to generate the second bit CSID2<1> of the second corrected slice ID according to the second chip kill signal CKILL-S2 that is deactivated at a logic “low” level and the second bit INV2<1> of the second inverted signal that is activated at a logic “high” level.

The corrected slice ID generation circuit 323 buffers the first slice ID SID1<1:0> having a binary bit set of “01” to generate the second corrected slice ID SCID2<1:0> having a binary bit set of “01” according to the second chip kill signal CKILL-S2 and the second inverted signal INV2<1:0>, which are both deactivated at a logic “low” level. The corrected slice ID generation circuit 323 generates the second corrected slice ID SCID2<1:0> having a binary bit set of “11” when the second chip kill signal CKILL-S2 that is activated at a logic “high” level is received. The corrected slice ID generation circuit 323 inversely buffers the first slice ID SID1<1:0>having a binary bit set of “01” to generate the second corrected slice ID SCID2<1:0> having a binary bit set of “10” according to the second chip kill signal CKILL-S2 that is deactivated at a logic “low” level and the second bit INV2<1> of the second inverted signal that is activated at a logic “high” level.

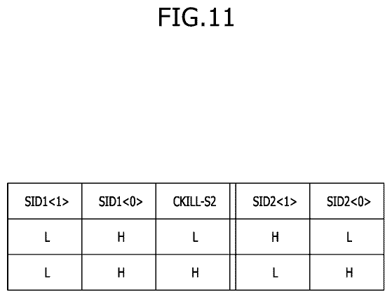

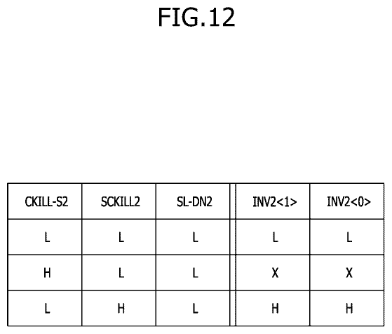

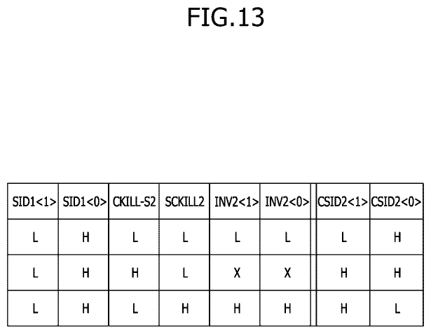

FIG. 11 is a table identifying signals transferred during an operation in which a second slice ID SID2<1:0> is generated in a second slice chip 102, such as shown in FIG. 8, FIG. 12 is a table identifying signals transferred during an operation in which a second inverted signal INV2<1:0> is generated in a slice ID calibration circuit 217, such as shown in FIG. 9, and FIG. 13 is a table identifying signals transferred during an operation that generates a second corrected slice ID CSID2<1:0> in the second slice ship 102, such as shown in FIG. 10.

Referring to FIG. 8 and a first row of FIG. 11, a slice ID generation circuit 215 of the second slice chip 102 up-counts a first slice ID SID1<1:0>, which is set to have a binary bit set of “01”, by one bit according to a second chip kill signal CKILL-S2 that is deactivated at a logic “low” level “L” to generate the second slice ID SID2<1:0> that is set to have a binary bit set of “10”. The second slice ID SID2<1:0> being set to have the binary bit set of “10” means that the second bit SID1<1> of the first slice ID is set at a logic “high” level “H” and the first bit SID1<0> of the first slice ID is set at a logic “low” level “L”. Referring to FIG. 8 and a second row of FIG. 11, the slice ID generation circuit 215 of the second slice chip 102 generates the second slice ID SID2<1:0> that is set to have the same binary bit set of “01” as the first slice ID SID1<1:0> according to the second chip kill signal CKILL-S2 activated at a logic “high” level “H”.

Referring to FIG. 9 and a first row of FIG. 12, an inverted signal generation circuit 301 of the slice ID calibration circuit 217 generates the second inverted signal INV2<1:0> that is set to have a binary bit set of “00” when the second down slice signal SL-DN2, a second synthetic chip kill signal SCKILL2, and a second chip kill signal CKILL-S2, which are all deactivated at a logic “low” level “L”, are received. Referring to FIG. 9 and a second row of FIG. 12, the inverted signal generation circuit 301 generates the second inverted signal INV2<1:0> that is set to have a binary bit set of a “don't care” state “XX” when the second chip kill signal CKILL-S2 activated at a logic “high” level “H” and the second down slice signal SL-DN2 and the second synthetic chip kill signal SCKILL2 that are both deactivated at a logic “low” level “L” are received. Referring to FIG. 9 and a third row of FIG. 12, the inverted signal generation circuit 301 generates the second inverted signal INV2<1:0> that is set to have a binary bit set of “11” when the second synthetic chip kill signal SCKILL2 activated at a logic “high” level “H” and the second down slice signal SL-DN2 and the second chip kill signal CKILL-S2 that are both deactivated at a logic “low” level “L” are received.

Referring to FIG. 9, FIG. 10, and a first row of FIG. 13, the corrected slice ID generation circuit 217 generates the second corrected slice ID SID2<1:0> having the same binary bit set of “01” as the first slice ID SID1<1:0> according to the second chip kill signal CKILL-S2 and the second synthetic chip kill signal SCKILL2 that are deactivated at a logic “low” level and the second inverted signal INV2<1:0> that is set to have a binary bit set of “00”. The second corrected slice ID CSID2 being set to have the binary bit set of “01” means that the second bit CSID2<1> of the second corrected slice ID is set at a logic “low” level “L” and the first bit CSID2<0> of the second corrected slice ID is set at a logic “high” level “H”. Referring to FIG. 9, FIG. 10, and a second row of FIG. 13, the corrected slice ID generation circuit 217 generates the second corrected slice ID CSID2<1:0> having a preset binary bit set of “11”, regardless of the second inverted signal INV2<1:0>, when the second chip kill signal CKILL-S2 activated at a logic “high” level is received. The second corrected slice ID CSID2 being set to have the binary bit set of “11” means that both the second bit CSID2<1>of the second corrected slice ID and the first bit CSID2<0> of the second corrected slice ID are set at a logic “high” level “H”. Referring to FIG. 9, FIG. 10, and a third row of FIG. 13, when the second chip kill signal CKILL-S2 deactivated at a logic “low” level “L” and the second synthetic chip kill signal SCKILL2 and the second inverted signal INV2<1:0> that are both activated at a logic “high” level “H” are received, the corrected slice ID generation circuit 217 inverts the first slice ID SID1<1:0> that is set to have a binary bit set of “01” to generate the second corrected slice ID CSID2<1:0> that is set to have a binary bit set of “10”.

FIG. 14 illustrates an embodiment of a third slice chip 103 included in the memory device, for example, as shown in FIG. 1.

As shown in FIG. 14, the third slice chip 103 includes NMOS transistors 221-1 and 221-2, buffers 222-1 and 222-2, an inverter 223, a slice ID generation circuit (SID GEN) 225, a slice ID calibration circuit (SID CAL) 227, and a synthetic chip kill signal generation circuit (SCKILL GEN) 229.

The NMOS transistor 221-1 operates as a driving device that drives a node nd221-1 to a logic “low” level. The NMOS transistor 221-2 operates as a driving device that drives a node nd221-2 to a logic “low” level. Both the node nd221-1 and the node nd221-2 may be initialized at a logic “low” level by the NMOS transistors 221-1 and 221-2. A logic level of the node nd221-1 may be set by a second bit SID2<1> of a second slice ID received through the fourth through-via 123 of FIG. 1. The logic level of the node nd221-2 may be set by a first bit SID2<0> of the second slice ID received through the fourth through-via 123.

The buffer 221-1 buffers a signal of the node nd221-1 to output the second bit SID2<1> of the second slice ID. The buffer 222-2 buffers a signal of the node nd221-2 to output the first bit SID2<0> of the second slice ID. For example, the buffers 222-1 and 222-2 may buffer and output the second slice ID SID2<1:0> input with a binary bit set of “10”. The second slice ID SID2<1:0> being set to have the binary bit set of “10” means that the second bit SID2<1> of the second slice ID is set at a logic “high” level and the first bit SID2<0> of the second slice ID is set at a logic “low” level.

The slice ID generation circuit 225 receives the second slice ID SID2<1:0> through the buffers 222-1 and 222-2 that are electrically connected to the slice ID generation circuit 225. The slice ID generation circuit 225 receives a third chip kill signal CKILL-S3 through a first input terminal F and receives an inverted third chip kill signal CKILL-S3, inverted by the inverter 223, through a second input terminal D. The third chip kill signal CKILL-S3 is activated when the third slice chip 103 is chip-killed. The slice ID generation circuit 225 generates a third slice ID SID3<1:0> from the second slice ID SID2<1:0> based on the third chip kill signal CKILL-S3 to output the third slice ID SID3<1:0> through the sixth through-via 133 of FIG. 1. The slice ID generation circuit 225 up-counts the second slice ID SID2<1:0> to generate the third slice ID SID3<1:0> when the third slice chip 103 is not chip-killed and a deactivated third chip kill signal CKILL-S3 is received. For example, the slice ID generation circuit 225 may up-count the second slice ID SID2<1:0>, which is set to have a binary bit set of “10”, by one bit to generate the third slice ID SID3<1:0> that is set to have a binary bit set of “11” when the deactivated third chip kill signal CKILL-S3 is received. The slice ID generation circuit 225 generates the third slice ID SID3<1:0> having the same binary bit set as the second slice ID SID2<1:0> when the third slice chip 103 is chip-killed and an activated third chip kill signal CKILL-S3 is received. For example, the slice ID generation circuit 225 may generate the third slice ID SID3<1:0> having the same binary bit set of “10” as the second slice ID SID2<1:0> when the activated third chip kill signal CKILL-S3 is received.

The slice ID calibration circuit 227 receives the second slice ID SID2<1:0> through the buffers 221-1 and 222-2 that are electrically connected to the slice ID calibration circuit 227. The slice ID calibration circuit 227 generates a third corrected slice ID CSID3<1:0> from the second slice ID SID2<1:0> based on a third synthetic chip kill signal SCKILL3, the third chip kill signal CKILL3, and a third down slice signal SL-DN3. Because the third down slice signal SL-DN3 is activated when the third slice chip 103 is at the lowest layer, the slice ID calibration circuit 227 receives the deactivated third down slice signal SL-DN3. The slice ID calibration circuit 227 is set to generate the third corrected slice ID CSID3<1:0> having a binary bit set according to the third synthetic chip kill signal SCKILL3 and the third chip kill signal CKILL-S3 when the deactivated third down slice signal SL-DN3 is received. For example, the slice ID calibration circuit 227 may be set to generate the third corrected slice ID CSID3<1:0> having a binary bit set of “11” when an activated third chip kill signal CKILL-S3 is received. As another example, the slice ID calibration circuit 227 may be set to invert the second slice ID SID2<1:0> having a binary bit set of “10” to generate the third corrected slice ID CSID3<1:0> having a binary bit set of “01” when an activated third synthetic chip kill signal SCKILL3 is received.

The synthetic chip kill signal generation circuit 229 generates the second synthetic chip kill signal SCKILL2 based on the third synthetic chip kill signal SCKILL3 and the third chip kill signal CKILL-S3. The synthetic chip kill signal generation circuit 229 generates the second synthetic chip kill signal SCKILL2 that is activated when one of the third synthetic chip kill signal SCKILL3 and the third chip kill signal CKILL-S3 is activated. When the third slice chip 103 is chip-killed and the activated third chip kill signal CKILL-S3 is received or the fourth slice chip 104 is chip-killed and the activated third synthetic chip kill signal SCKILL3 is received, the synthetic chip kill signal generation circuit 229 generates the second synthetic chip kill signal SCKILL2 that is activated. Accordingly, the synthetic chip kill signal generation circuit 229 generates the second synthetic chip kill signal SCKILL2 that is activated when one of the third slice chip 103 and the fourth slice chip 104 is chip-killed.

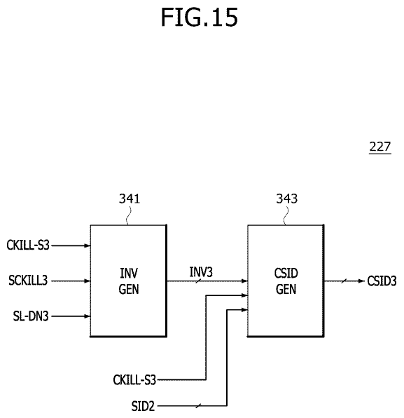

FIG. 15 illustrates an embodiment of a slice ID calibration circuit 227, for example, as shown in FIG. 14.

As shown in FIG. 15, the slice ID calibration circuit 227 includes an inverted signal generation circuit (INV GEN) 341 and a corrected slice ID generation circuit (CSID GEN) 343.

The inverted signal generation circuit 341 generates a third inverted signal INV3 based on a third synthetic chip kill signal SCKILL3, a third chip kill signal CKILL-S3, and the third down slice signal SL-DN3. The inverted signal generation circuit 341 receives a deactivated third down slice signal SL-DN3 to generate the third inverted signal INV3 having a binary bit set that is set according to the third synthetic chip kill signal SCKILL3 and the third chip kill signal CKILL-S3. For example, the inverted signal generation circuit 341 generates the third inverted signal INV3<1:0> that is set to have a binary bit set of “00” when the third synthetic chip kill signal SCKILL3 and the third chip kill signal CKILL-S3 that are both deactivated are received. As another example, the inverted signal generation circuit 341 may generate the third inverted signal INV3<1:0> that is set to have a binary bit set of a “don't care” state “X” when an activated third chip kill signal CKILL-S3 is received. As another example, the inverted signal generation circuit 341 may generate the third inverted signal INV3<1:0> that is set to have a binary bit set of “11” when an activated third synthetic chip kill signal SCKILL3 is received.

The corrected slice ID generation circuit 343 receives the third inverted signal INV3 from the inverted signal generation circuit 341 that is electrically connected to the corrected slice ID generation circuit 343. The corrected slice ID generation circuit 343 generates a third corrected slice ID CSID3 according to the second slice ID SID2 based on the third chip kill signal CKILL-S3 and the third inverted signal INV3. The corrected slice ID generation circuit 343 receives the third chip kill signal CKILL-S3 and the third inverted signal INV3 that are both deactivated to generate the third corrected slice ID CSID3 that is set to have the same binary bit set as the second slice ID SID2. For example, the corrected slice ID generation circuit 343 may generate the third corrected slice ID CSID3 having a binary bit set of “10” when the second slice ID SID2 having a binary bit set of “10” is received. The corrected slice ID generation circuit 343 generates the third corrected slice ID CSID3 that is set to have a preset binary bit set when an activated third chip kill signal CKILL-S3 is received. For example, the corrected slice ID generation circuit 343 may generate the third corrected slice ID CSID3<1:0> having a binary bit set of “11” when the activated third chip kill signal CKILL-S3 is received. The corrected slice ID generation circuit 343 inverts the second slice ID SID2 to generate the third corrected slice ID CSID3 when the deactivated third chip kill signal CKILL-S3, the activated third synthetic chip kill signal SCKILL3, and the activated third inverted signal INV3 are received. For example, the corrected slice ID generation circuit 343 may invert the second slice ID SID2 having a binary bit set of “10” to generate the third corrected slice ID CSID3 having a binary bit set of “01” when the deactivated third chip kill signal CKILL-S3, the activated third synthetic chip kill signal SCKILL3, and the activated third inverted signal INV3 are received.

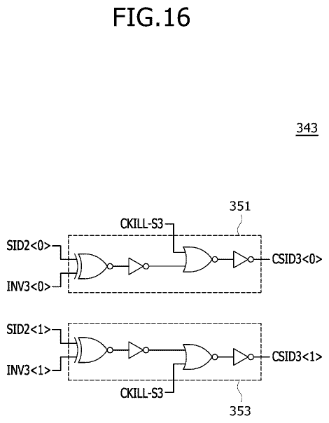

FIG. 16 illustrates an embodiment of a corrected slice ID generation circuit 343, for example, as shown in FIG. 15.

As shown in FIG. 16, the corrected slice ID generation circuit 343 includes a first corrected slice ID generation circuit 351 and a second corrected slice ID generation circuit 353.

The first corrected slice ID generation circuit 351 generates a first bit CSID3<0> of the third corrected slice ID that is set at a logic “high” level when the third chip kill signal CKILL-S3 activated at a logic “high” level is received. The first corrected slice ID generation circuit 351 buffers a first bit SID2<0> of the second slice ID to generate the first bit CSID3<0> of the third corrected slice ID according to the third chip kill signal CKILL-S3 and the first bit INV3<0> of the third inverted signal that are both deactivated at a logic “low” level. According to the third chip kill signal CKILL-S3 deactivated at a logic “low” level and the first bit INV3<0> of the third inverted signal activated at a logic “high” level, the first corrected slice ID generation circuit 351 inverts the first bit SID2<0> of the second slice ID to generate the first bit CSID3<0> of the third corrected slice ID.

The second corrected slice ID generation circuit 353 generates a second bit CSID3<2> of the third corrected slice ID that is set at a logic “high” level when the third chip kill signal CKILL3 activated at a logic “high” level is received. The second corrected slice ID generation circuit 353 buffers a second bit SID2<1> of the second slice ID to generate the second bit CSID3<1> of the third corrected slice ID according to the third chip kill signal CKILL-S3 and the second bit INV3<1> of the third inverted signal that are all deactivated at a logic “low” level. According to the third chip kill signal CKILL-S3 deactivated at a logic “low” level and the second bit INV3<1> of the third inverted signal activated at a logic “high” level, the second corrected slice ID generation circuit 353 inversely buffers the second bit SID2<1> of the second slice ID to generate the second bit CSID3<1> of the third corrected slice ID.

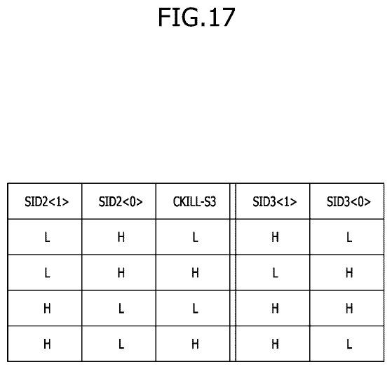

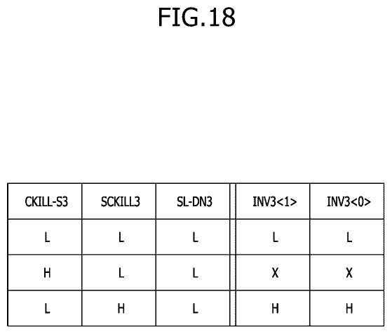

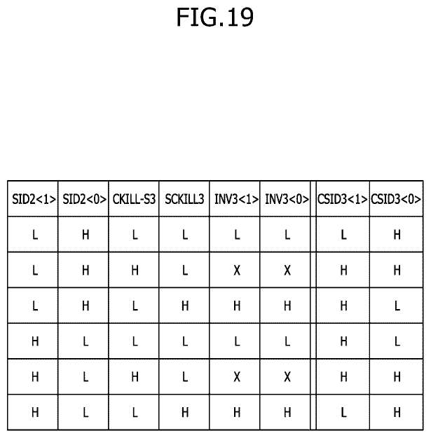

FIG. 17 is a table identifying signals transferred during an operation in which a third slice ID SID3<1:0> is generated in a third slice chip 103, such as shown in FIG. 14, FIG. 18 is a table identifying signals transferred during an operation in which a third inverted signal INV3<1:0> is generated in a slice ID calibration circuit 227, such as shown in FIG. 15, and FIG. 19 is a table identifying signals transferred during an operation that generates a third corrected slice ID CSID3<1:0>in the third slice chip 103, such as shown in FIG. 16.

Referring to FIG. 14 and a first row of FIG. 17, the slice ID generation circuit 225 of the third slice chip 103 up-counts a second slice ID SID2<1:0>, which is set to have a binary bit set of “01”, by one bit to generate the third slice ID SID3<1:0> that is set to have a binary bit set of “10” according to the third chip kill signal CKILL-S3 deactivated at a logic “low” level “L”. Referring to FIG. 14 and a second row of FIG. 17, the slice ID generation circuit 225 of the third slice chip 103 generates the third slice ID SID3<1:0> that is set to have the same binary bit set of “01” as the second slice ID SID2<1:0> according to the third chip kill signal CKILL3 activated at a logic “high” level “H”. Referring to FIG. 14 and a third row of FIG. 17, the slice ID generation circuit 225 of the third slice chip 103 up-counts the second slice ID SID2<1:0>, which is set to have a binary bit set of “10”, by one bit to generate the third slice ID SID3<1:0> that is set to have a binary bit set of “11” according to the third chip kill signal CKILL3 deactivated at a logic “low” level “L”. Referring to FIG. 14 and a fourth row of FIG. 17, the slice ID generation circuit 225 of the third slice chip 103 generates the third slice ID SID3<1:0> that is set to have the same binary bit set of “10” as the second slice ID SID2<1:0> according to the third chip kill signal CKILL3 activated at a logic “high” level “H”.

Referring to FIG. 15 and a first row of FIG. 18, an inverted signal generation circuit 301 of the slice ID calibration circuit 227 generates the third inverted signal INV3<1:0> that is set to have a binary bit set of “00” when the third down slice signal SL-DN3, the third synthetic chip kill signal SCKILL3, and the third chip kill signal CKILL-S3 that are all deactivated at a logic “low” level “L” are received. Referring to FIG. 15 and a second row of FIG. 18, when the third chip kill signal CKILL-S3 activated at a logic “high” level “H” and the third down slice signal SL-DN3 and the third synthetic chip kill signal SCKILL3 that are deactivated at a logic “low” level “L” are received, the inverted signal generation circuit 301 generates the third inverted signal INV3<1:0> that is set to have a binary bit set of a “don't care” state “XX”. Referring to FIG. 15 and a third row of FIG. 18, when the third synthetic chip kill signal SCKILL3 activated at a logic “high” level “H” and the third down slice signal SL-DN3 and the third chip kill signal CKILL-S3 that are both deactivated at a logic “low” level “L” are received, the inverted signal generation circuit 301 generates the third inverted signal INV3<1:0> that is set to have a binary bit set of “11”.

Referring to FIG. 15, FIG. 16, and a first row of FIG. 19, the corrected slice ID generation circuit 227 generates the third corrected slice ID CSID3<1:0> having the same binary bit set of “01” as the second slice ID SID2<1:0> according to the third chip kill signal CKILL-S3 and the third synthetic chip kill signal SCKILL3 that are deactivated at a logic “low” level and the third inverted signal INV3<1:0> that is set to have a binary bit set of “00”. Referring to FIG. 15, FIG. 16, and a second row of FIG. 19, the corrected slice ID generation circuit 227 generates the third corrected slice ID CSID3<1:0> having a preset binary bit set of “11”, regardless of the third inverted signal INV3<1:0> when the third chip kill signal CKILL-S3 activated at a logic “high” level “H” is received. Referring to FIG. 15, FIG. 16, and a third row of FIG. 19, when the third chip kill signal CKILL-S3 deactivated at a logic “low” level “L” and the third synthetic chip kill signal SCKILL3 and the third inverted signal INV3<1:0> that are all activated at a logic “high” level “H” are received, the corrected slice ID generation circuit 227 inverts the first slice ID SID1<1:0> that is set to have a binary bit set of “01” to generate the third corrected slice ID CSID3<1:0> to have a binary bit set of “01”. Referring to FIG. 15, FIG. 16, and a fourth row of FIG. 19, according to the third chip kill signal CKILL-S3 and the third synthetic chip kill signal SCKILL3 that are deactivated at a logic “low” level “L” and the third inverted signal INV3<1:0> that is set to have a binary bit set of “00”, the corrected slice ID generation circuit 227 generates the third corrected slice ID CSID3<1:0> having the same binary bit set as the first slice ID SID1<1:0> having a binary bit set of “10”. Referring to FIG. 15, FIG. 16, and a fifth row of FIG. 19, the corrected slice ID generation circuit 227 generates the third corrected slice ID CSID3<1:0> having a preset binary bit set of “11”, regardless of the third inverted signal INV3<1:0> when the third chip kill signal CKILL-S3 activated at a logic “high” level “H” is received. Referring to FIG. 15, FIG. 16, and a sixth row of FIG. 19, when the third chip kill signal CKILL-S3 deactivated at a logic “low” level “L” and the third synthetic chip kill signal SCKILL3 and the third inverted signal INV3<1:0> that are all activated at a logic “high” level “H” are received, the corrected slice ID generation circuit 227 inverts the first slice ID SID1<1:0> that is set to have a binary bit set of “10” to generate the third corrected slice ID CSID3<1:0> that is set to have a binary bit set of “01”.

FIG. 20 illustrates an embodiment of a fourth slice chip 104, for example, as shown in FIG. 1.

As shown in FIG. 20, the fourth slice chip 104 includes NMOS transistors 231-1 and 231-2, buffers 232-1 and 232-2, an inverter 233, a slice ID generation circuit (SID GEN) 235, a slice ID calibration circuit (SID CAL) 237, and a synthetic chip kill signal generation circuit (SCKILL GEN) 239.

The NMOS transistor 231-1 operates as a driving device that drives a node nd231-1 to a logic “low” level. The NMOS transistor 231-2 operates as a driving device that drives a node nd231-2 to a logic “low” level. Both the node nd231-1 and the node nd231-2 may be initialized at a logic “low” level by the NMOS transistors 231-1 and 231-2. A logic level of the node nd231-1 may be set by the sixth through-via 133 of FIG. 1. The logic level of the node nd231-2 may be set by a first bit SID3<0> of a third slice ID received by the sixth through-via 133.

The buffer 232-1 buffers a signal of the node nd231-1 to output the second bit SID3<1> of the third slice ID. The buffer 232-2 buffers a signal of the node nd231-2 to output the first bit SID3<0> of the third slice ID. For example, the buffers 232-1 and 232-2 may buffer and output the third slice ID SID3<1:0> input with a binary bit set of “11”. The third slice ID SID3<1:0> being set to have the binary bit set of “11” means that both the second bit SID3<1> of the third slice ID and the first bit SID3<0> of the third slice ID are set at a logic “high” level.

The slice ID generation circuit 235 receives the third slice ID SID3<1:0> through the buffers 232-1 and 232-2 that are electrically connected to the slice ID generation circuit 235. The slice ID generation circuit 235 receives a fourth chip kill signal CKILL-S4 through a first input terminal F and receives an inverted fourth chip kill signal CKILL-S4, inverted by the inverter 233, through a second input terminal D. The fourth chip kill signal CKILL-S4 is activated when the fourth slice chip 104 is chip-killed. The slice ID generation circuit 235 generates the fourth slice ID SID4<1:0> from the third slice ID SID3<1:0> based on the fourth chip kill signal CKILL-S4. When the fourth slice chip 104 is not chip-killed and a deactivated fourth chip kill signal CKILL-S4 is received, the slice ID generation circuit 235 up-counts the third slice ID SID3<1:0> to generate the fourth slice ID SID4<1:0>. For example, the slice ID generation circuit 235 may up-count the third slice ID SID3<1:0> having a binary bit set of “11” by one bit to generate the fourth slice ID SID4<1:0> that is set to have a binary bit set of “00” when the deactivated fourth chip kill signal CKILL-S4 is received. When the fourth slice chip 104 is chip-killed and an activated fourth chip kill signal CKILL-S4 is received, the slice ID generation circuit 235 generates the fourth slice ID SID4<1:0> having the same binary bit set as the third slice ID SID3<1:0>. For example, the slice ID generation circuit 235 may generate the fourth slice ID SID4<1:0> having the same binary bit set of “11” as the third slice ID SID3<1:0> when the activated fourth chip kill signal CKILL-S4 is received.

The slice ID calibration circuit 237 receives the third slice ID SID3<1:0> through the buffers 232-1 and 232-2 that are electrically connected to the slice ID calibration circuit 237. The slice ID calibration circuit 237 generates the fourth corrected slice ID CSID4<1:0> from the third slice ID SID3<1:0> based on the fourth chip kill signal CKILL-S4 and a fourth down slice signal SL-DN4. Because the fourth down slice signal SL-DN4 is activated when the fourth slice chip 104 is at the lowest layer, the slice ID calibration circuit 237 receives a deactivated fourth down slice signal SL-DN4. The slice ID calibration circuit 237 is set to generate a fourth corrected slice ID CSID4<1:0> having a binary bit set according to the fourth chip kill signal CKILL-S4 when the deactivated fourth down slice signal SL-DN4 is received. For example, the slice ID calibration circuit 237 may be set to generate the fourth corrected slice ID CSID4<1:0> having a binary bit set of “11” when an activated fourth chip kill signal CKILL-S4 is received. As another example, the slice ID calibration circuit 237 may be set to generate the fourth corrected slice ID CSID4<1:0> having a binary bit set of a “don't care” state “XX” when the deactivated fourth chip kill signal CKILL-S4 is received.

The synthetic chip kill signal generation circuit 239 generates a third synthetic chip kill signal SCKILL3 based on the fourth chip kill signal CKILL-S4. The synthetic chip kill signal generation circuit 239 generates the third synthetic chip kill signal SCKILL3 that is activated when the fourth chip kill signal CKILL-S4 is activated. When the fourth slice chip 104 is chip-killed and an activated fourth chip kill signal CKILL-S4 is received, the synthetic chip kill signal generation circuit 239 generates the third synthetic chip kill signal SCKILL3 that is activated.

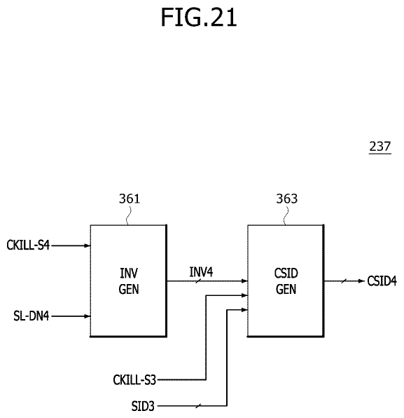

FIG. 21 illustrates an embodiment of a slice ID calibration circuit 237, for example, as shown in FIG. 20.

As shown in FIG. 21, the slice ID calibration circuit 237 includes an inverted signal generation circuit (INV GEN) 361 and a corrected slice ID generation circuit (CSID GEN) 363.

The inverted signal generation circuit 361 generates a fourth inverted signal INV4 based on a fourth chip kill signal CKILL-S4 and a fourth down slice signal SL-DN4. The inverted signal generation circuit 361 receives a deactivated fourth down slice signal SL-DN4 to generate the fourth inverted signal INV4 having a binary bit set that is set according to the fourth synthetic chip kill signal SCKIIL4. For example, the inverted signal generation circuit 361 may generate the fourth inverted signal INV4 set to have a binary bit set of a “don't care” state “X” when the deactivated fourth chip kill signal CKILL-S4 is received.

The corrected slice ID generation circuit 363 receives the fourth inverted signal INV4 from the inverted signal generation circuit 361 that is electrically connected to the corrected slice ID generation circuit 363. The corrected slice ID generation circuit 363 generates a fourth corrected slice ID CSID4 according to the third slice ID SID3 based on the fourth chip kill signal CKILL-S4 and the fourth inverted signal INV4. The corrected slice ID generation circuit 363 receives the fourth chip kill signal CKILL-S4 and the fourth inverted signal INV4 that are both deactivated to generate the fourth corrected slice ID CSID4 that is set to have the same binary bit set as a third slice ID SID3. For example, the corrected slice ID generation circuit 363 may generate the fourth corrected slice ID CSID4 having a binary bit set of “10” when the third slice ID SID3 having a binary bit set of “10” is received. The corrected slice ID generation circuit 363 generates the fourth corrected slice ID CSID4 that is set to have a preset binary bit set when an activated fourth chip kill signal CKILL-S4 is received. For example, the corrected slice ID generation circuit 363 may generate the fourth corrected slice ID CSID4<1:0> having a binary bit set of “11” when the activated fourth chip kill signal CKILL-S4 is received.

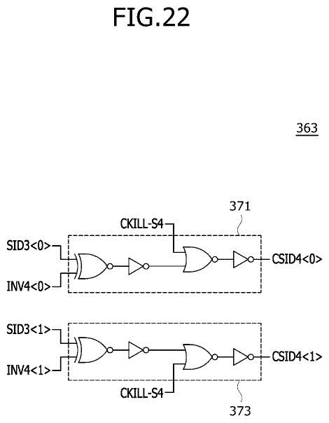

FIG. 22 illustrates an embodiment of a corrected slice ID generation circuit 363, for example, as shown in FIG. 21.

As shown in FIG. 22, the corrected slice ID generation circuit 363 includes a first corrected slice ID generation circuit 371 and a second corrected slice ID generation circuit 373.

The first corrected slice ID generation circuit 371 generates a first bit CSID4<0> of a fourth corrected slice ID that is set at a logic “high” level when the fourth chip kill signal CKILL-S4 activated at a logic “high” level is received. According to the fourth chip kill signal CKILL-S4 and a first bit INV4<0> of the fourth inverted signal that are all deactivated at a logic “low” level, the first corrected slice ID generation circuit 371 buffers a first bit SID3<0> of a third slice ID to generate a first bit CSID4<0> of the fourth corrected slice ID. According to the fourth chip kill signal CKILL-S4 deactivated at a logic “low” level and the first bit INV4<0> of the fourth inverted signal activated at a logic “high” level, the first corrected slice ID generation circuit 371 inversely buffers the first bit SID3<0> of the third slice ID to generate the first bit CSID4<0> of the fourth corrected slice ID.

The second corrected slice ID generation circuit 373 generates a second bit CSID4<1> of the fourth corrected slice ID that is set at a logic “high” level when the fourth chip kill signal CKILL-S4 activated at a logic “high” level is received. According to the fourth chip kill signal CKILL-S4 and a second bit INV4<1> of the fourth inverted signal INV4<1:0> that are all deactivated at a logic “low” level, the second corrected slice ID generation circuit 373 buffers a second bit SID3<1> of the third slice ID to generate a second bit CSID4<1> of the fourth corrected slice ID. According to the fourth chip kill signal CKILL-S4 deactivated at a logic “low” level and the second bit INV4<1> of the fourth inverted signal INV4<1:0> activated at a logic “high” level, the second corrected slice ID generation circuit 373 inversely buffers the second bit SID3<1> of the third slice ID to generate the second bit CSID4<1> of the fourth corrected slice ID.

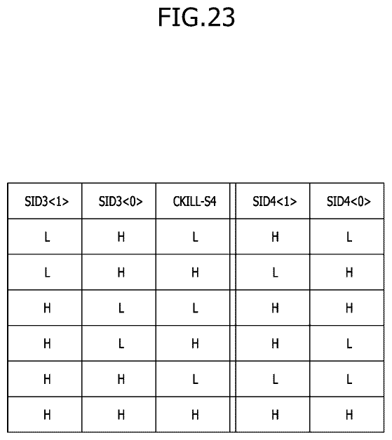

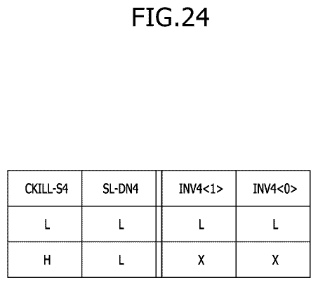

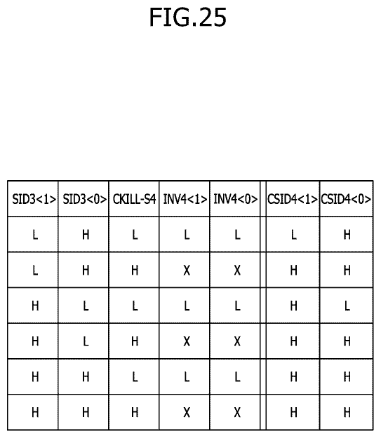

FIG. 23 is a table identifying signals transferred during an operation in which a fourth slice ID SID4<1:0> is generated in a fourth slice chip 104, such as shown in FIG. 20, FIG. 24 is a table identifying signals transferred during an operation in which a fourth inverted signal INV4<1:0> is generated in a slice ID calibration circuit 237, such as shown in FIG. 21, and FIG. 25 is a table identifying signals transferred during an operation that generates a fourth corrected slice ID CSID4<1: 0> in the fourth slice chip 104, such as shown in FIG. 22.

Referring to FIG. 20 and a first row of FIG. 23, the slice ID generation circuit 235 of the fourth slice chip 104 up-counts a third slice ID SID3<1:0>, which is set to have a binary bit set of “01”, by one bit according to a fourth chip kill signal CKILL-S4 deactivated at a logic “low” level “L” to generate the fourth slice ID SID4<1:0>that is set to have a binary bit set of “10”. Referring to FIG. 20 and a second row of FIG. 23, the slice ID generation circuit 235 of the fourth slice chip 104 generates the fourth slice ID SID4<1:0> that is set to have the same binary bit set of “01” as the third slice ID SID3<1:0> according to the fourth chip kill signal CKILL-S4 activated at a logic “high” level “H”. Referring to FIG. 20 and a third row of FIG. 23, the slice ID generation circuit 235 of the fourth slice chip 104 up-counts the third slice ID SID3<1:0>, which is set to have a binary bit set of “10”, by one bit according to the fourth chip kill signal CKILL-S4 deactivated at a logic “low” level “L” to generate the fourth slice ID SID4<1:0> that is set to have a binary bit set of “11”. Referring to FIG. 20 and a fourth row of FIG. 23, the slice ID generation circuit 235 of the fourth slice chip 104 generates the fourth slice ID SID4<1:0> that is set to have the same binary bit set of “10” as the third slice ID SID3<1:0> according to the fourth chip kill signal CKILL-S4 activated at a logic “high” level “H”. Referring to FIG. 20 and a fifth row of FIG. 23, the slice ID generation circuit 235 of the fourth slice chip 104 up-counts the third slice ID SID3<1:0>, which is set to have a binary bit set of “11”, by one bit according to the fourth chip kill signal CKILL-S4 deactivated at a logic “low” level “L” to generate the fourth slice ID SID4<1:0> that is set to have a binary bit set of “00”. Referring to FIG. 20 and a sixth row of FIG. 23, the slice ID generation circuit 235 of the fourth slice chip 104 generates the fourth slice ID SID4<1:0> that is set to have the same binary bit set of “11” as the third slice ID SID3<1:0> according to the fourth chip kill signal CKILL-S4 activated at a logic “high” level “H”.

Referring to FIG. 21 and a first row of FIG. 24, when a fourth down slice signal SL-DN4 and the fourth chip kill signal CKILL-S4 that are both deactivated at a logic “low” level “L” are received, an inverted signal generation circuit 301 of the slice ID calibration circuit 237 generates the fourth inverted signal INV4<1:0> that is set to have a binary bit set of “00”. Referring to FIG. 21 and a second row of FIG. 24, when the fourth chip kill signal CKILL-S4 activated at a logic “high” level “H” and the fourth down slice signal SL-DN4 deactivated at a logic “low” level “L” are received, the inverted signal generation circuit 301 generates the fourth inverted signal INV4<1:0> that is set to have a binary bit set of a “don't care” state “XX”.

Referring to FIG. 21, FIG. 23, and a first row of FIG. 25, according to the fourth chip kill signal CKILL-S4 deactivated at a logic “low” level “L” and the fourth inverted signal INV4<1:0> that is set to have a binary bit set of “00”, a corrected slice ID generation circuit 363 of the slice ID calibration circuit 237 generates the fourth corrected slice ID CSID4 having the same binary bit set of “01” as the third slice ID SID3. Referring to FIG. 21, FIG. 23, and a second row of FIG. 25, when the fourth chip kill signal CKILL-S4 activated at a logic “high” level “H” is received, the corrected slice ID generation circuit 363 generates the fourth corrected slice ID CSID4 having a binary bit set of “11”, regardless of the fourth inverted signal INV4<1:0>. Referring to FIG. 21, FIG. 23, and a third row of FIG. 25, according to the fourth chip kill signal CKILL-S4 deactivated at a logic “low” level “L” and the fourth inverted signal INV4<1:0> that is set to have a binary bit set of “00”, the corrected slice ID generation circuit 363 generates the fourth corrected slice ID CSID4 having the same binary bit set of “10” as the third slice ID SID3. Referring to FIG. 21, FIG. 23, and a fourth row of FIG. 25, when the fourth chip kill signal CKILL-S4 activated at a logic “high” level “H” is received, the corrected slice ID generation circuit 363 generates the fourth corrected slice ID CSID4 having a preset binary bit set of “11”, regardless of the fourth inverted signal INV4<1:0>. Referring to FIG. 21, FIG. 23, and a fifth row of FIG. 25, according to the fourth chip kill signal CKILL-S4 deactivated at a logic “low” level “L” and the fourth inverted signal INV4<1:0> that is set to have a binary bit set of “00”, the corrected slice ID generation circuit 363 generates the fourth corrected slice ID CSID4 having the same binary bit set of “11” as the third slice ID SID3. Referring to FIG. 21, FIG. 23, and a sixth row of FIG. 25, when the fourth chip kill signal CKILL-S4 activated at a logic “high” level “H” is received, the corrected slice ID generation circuit 363 generates the fourth corrected slice ID CSID4 having a preset binary bit set of “11”, regardless of the fourth inverted signal INV4<1:0>.

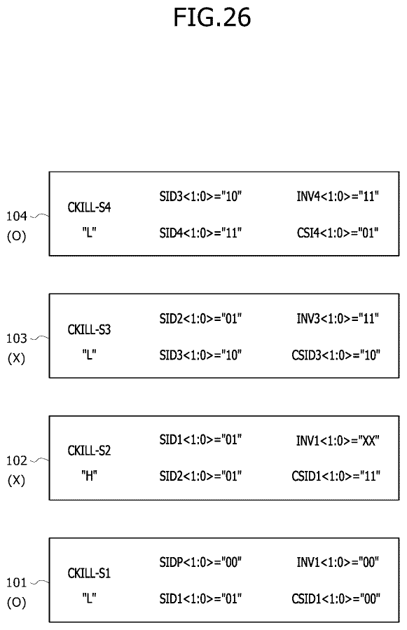

FIG. 26 to FIG. 28 illustrate a memory device in which corrected slice IDs are generated when chip-kill occurs in a second slice chip 102, a third slice chip 103, and a fourth slice chip 104 in a memory device 10 according to an embodiment of the present disclosure, as shown in FIG. 1.

Referring to FIG. 26, an operation is described in which first to fourth corrected slice IDs CSID1<1: 0>, CSID2<1:0>, CSID3<1:0>, and CSID4<1:0> are generated in the first slice chip 101, the second slice chip 102, the third slice chip 103, and the fourth slice chip 104, respectively, when the second slice chip 102 is chip-killed.

First, because a first chip kill signal CKILL-S1 is deactivated at a logic “low” level “L” in the first slice chip 101, a pre-slice ID SIDP<1:0> that is set to have a binary bit set of “00” is up-counted by one bit and a first slice ID SID1<1:0> that is set to have a binary bit set of “01” is generated. In addition, the first corrected slice ID CSID1<1:0> that is set to have the same binary bit set of “00” as the pre-slice ID SIDP<1:0> is generated based on a first inverted signal INV1<1:0> that is set to have a binary bit set of “00” in the first slice chip 101. The first slice chip 101 may maintain the operation based on the first corrected slice ID CSID1<1:0> that is set to have the binary bit set of “00”.

Next, because a second chip kill signal CKILL-S2 is activated at a logic “high” level “H” in the second slice chip 102, a second slice ID SID2<1:> that is set to have the same binary bit set of “01” as the first slice ID SID1<1:0> is generated. In addition, a second corrected slice ID SCID2<1:0> that is set to have a binary bit set of “11” is generated in the second slice chip 102, regardless of a second inverted signal INV2<1:0>. The second slice chip 102 may be stopped from operating based on the second corrected slice ID SCID2<1:0> that is set to have the binary bit set of “11”.

Next, because a third chip kill signal CKILL-S3 is deactivated at a logic “low” level “L” in the third slice chip 103, the second slice ID SID2<1:> that is set to have a binary bit set of “01” is up-counted by one bit and a third slice ID SID3<1:0> that is set to have a binary bit set of “10” is generated. In addition, the second slice ID SID2<1:0> that is set to have a binary bit set of “01” is inverted by a third inverted signal INV3<1:0> that is set to have a binary bit set of “11” in the third slice chip 103, and the third corrected slice ID CSID3<1:0> that is set to have a binary bit set of “10” is generated. The third slice chip 103 may stop the operation based on the third corrected slice ID CSID3<1:0> that is set to have the binary bit set of “10”.

Next, because a fourth chip kill signal CKILL-S4 is deactivated at a logic “low” level “L” in the fourth slice chip 104, the third slice ID SID3<1:0> that is set to have the binary bit set of “10” is up-counted by one bit to generate a fourth slice ID SID4<1:0> that is set to have a binary bit set of “11”. In addition, the third slice ID SID2<1:0>that is set to have the binary bit set of “10” is inverted by a fourth inverted signal INV4<1:0> that is set to have the binary bit set of “11” in the fourth slice chip 103, and a fourth corrected slice ID CSID4<1:0> that is set to have a binary bit set of “01” is generated. The fourth slice chip 103 may maintain operation by the fourth corrected slice ID CSID4<1:0> that is set to have a binary bit set of “01”.

As described above, the memory device 10 is set so that only the first slice chip 101 at the lowest layer and the fourth slice chip 104 at the highest layer operate based on the first to fourth corrected slice IDs CSID1<1:0>, CSID2<1:0>, CSID3<1:0>, and CSID4<1:0> when the second slice chip 102 is chip-killed, thereby allowing the memory device 10 to maintain a stable operation even after the chip-kill.

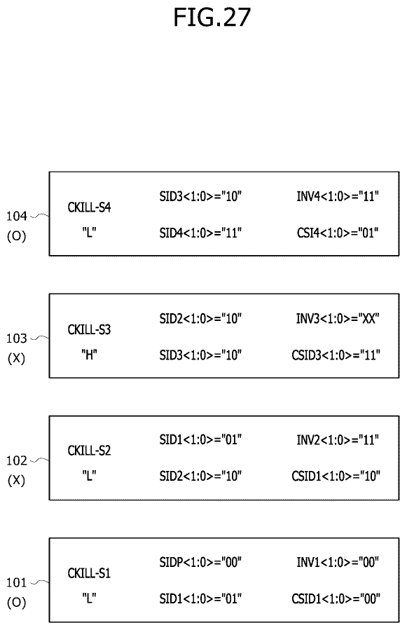

Referring to FIG. 27, an operation is described in which the first to fourth corrected slice IDs CSID1<1:0>, CSID2<1:0>, CSID3<1:0>, and CSID4<1:0>are generated in the first slice chip 101, the second slice chip 102, the third slice chip 103, and the fourth slice chip 104, respectively, when the third slice chip 103 is chip-killed.

First, because the first chip kill signal CKILL-S1 is deactivated at a logic “low” level “L” in the first slice chip 101, the pre-slice ID SIDP<1:0> that is set to have a binary bit set of “00” is up-counted by one bit and the first slice ID SID1<1:0> that is set to have a binary bit set of “01” is generated. In addition, in the first slice chip 101, the first corrected slice ID CSID1<1:0> that is set to have the same binary bit set of “00” as the pre-slice ID SIDP<1:0> is generated based on the first inverted signal INV1<1:0> that is set to have a binary bit set of “00”. The first slice chip 101 can maintain the operation based on the first corrected slice ID CSID1<1:0> that is set to have the binary bit set of “00”.

Next, because the second chip kill signal CKILL-S2 is deactivated at a logic “low” level “L” in the second slice chip 102, the first slice ID SID1<1:0> that is set to have a binary bit set of “01” is up-counted by one bit to generate the second slice ID SID2<1:0> that is set to have a binary bit set of “10”. In addition, in the second slice chip 102, the first slice ID SID1<1:0> that is set to have the binary bit set of “01” is inverted by the second inverted signal INV2<1:0> that is set to have a binary bit set of “11” to generate the second corrected slice ID CSID2<1:0> that is set to have a binary bit set of “10”. The third slice chip 103 may be stopped from operating based on the second corrected slice ID CSID2<1:0> that is set to have the binary bit set of “10”.

Next, because the third chip kill signal CKILL-S3 is activated at a logic “high” level “H” in the third slice chip 103, the third slice ID SID3<1:0> that is set to have the same binary bit set of “10” as the second slice ID SID2<1:0> is generated. In addition, the third corrected slice ID CSID3<1:0> that is set to have a binary bit set of “11” is generated, regardless of the third inverted signal INV3<1:0> in the third slice chip 103. The third slice chip 103 may be stopped from operating based on the third corrected slice ID CSID3<1:0> that is set to have the binary bit set of “11”.

Next, because the fourth chip kill signal CKILL-S4 is deactivated at a logic “low” level “L” in the fourth slice chip 104, the third slice ID SID3<1:0> that is set to have a binary bit set of “10” is up-counted by one bit to generate the fourth slice ID SID4<1:0> that is set to have a binary bit set of “11”. In addition, in the fourth slice chip 104, the third slice ID SID3<1:0> that is set to have a binary bit set of “10” is inverted by the fourth inverted signal INV4<1:0> that is set to have a binary bit set of “11” to generate the fourth corrected slice ID CSID4<1:0> that is set to have a binary bit set of “01”. The fourth slice chip 103 may maintain the operation based on the fourth corrected slice ID CSID4<1:0> that is set to have the binary bit set of “01”.

As described above, the memory device 10 is set so that only the first slice chip 101 at the lowest layer and the fourth slice chip 104 at the highest layer are operated based on the first to fourth corrected slice IDs CSID1<1:0>, CSID2<1:0>, CSID3<1:0>, and CSID4<1:0> when the third slice chip 103 is chip-killed, thereby allowing the memory device 10 to maintain a stable operation even after the chip-kill.

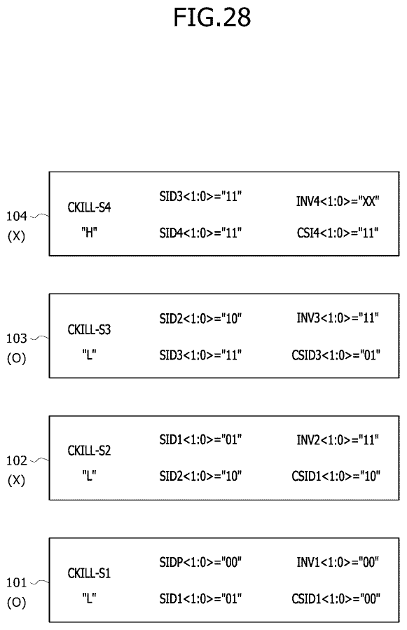

Referring to FIG. 28, an operation is described in which the first to fourth corrected slice IDs CSID1<1:0>, CSID2<1:0>, CSID3<1:0>, and CSID4<1:0> are generated in the first slice chip 101, the second slice chip 102, the third slice chip 103, and the fourth slice chip 104, respectively, when the fourth slice chip 104 is chip-killed.

First, because the first chip kill signal CKILL-S1 is deactivated at a logic “low” level “L” in the first slice chip 101, the pre-slice ID SIDP<1:0> that is set to have a binary bit set of “00” is up-counted by one bit to generate the first slice ID SID1<1:0> that is set to have a binary bit set of “01”. In addition, in the first slice chip 101, the first corrected slice ID CSID1<1:0> that is set to have the same binary bit set of “00” as the pre-slice ID SIDP<1:0> is generated based on the first inverted signal INV1<1:0> that is set to have a binary bit set of “00”. The first slice chip 101 can maintain the operation based on the first corrected slice ID CSID1<1:0> that is set to have the binary bit set of “00”.

Next, because the second chip kill signal CKILL-S2 is deactivated at a logic “low” level in the second slice chip 102, the first slice ID SID1<1:0> that is set to have a binary bit set of “01” is up-counted by one bit to generate the second slice ID SID2<1:0> that is set to have a binary bit set of “10”. In addition, in the second slice chip 102, the first slice ID SID1<1:0> that is set to have the binary bit set of “01” is inverted by the second inverted signal INV2<1:0> that is set to have a binary bit set of “11” to generate the second corrected slice ID CSID2<1:0> that is set to have a binary bit set of “10”. The third slice chip 103 may be stopped from operating based on the second corrected slice ID CSID2<1:0> that is set to have the binary bit set of “10”.

Next, because the third chip kill signal CKILL-S3 is deactivated at a logic “low” level “L” in the third slice chip 103, the second slice ID SID2<1:0> that is set to have a binary bit set of “10” is up-counted by one bit to generate the third slice ID SID3<1:0> that is set to have a binary bit set of “11”. In addition, in the third slice chip 103, the second slice ID SID2<1:0> that is set to have the binary bit set of “10” is inverted by the third inverted signal INV3<1:0> that is set to have a binary bit set of “11” to generate the third corrected slice ID CSID3<1:0> that is set to have a binary bit set of “01”. The third slice chip 103 may maintain the operation based on the third corrected slice ID CSID3<1:0> that is set to have the binary bit set of “01”.

Next, because the fourth chip kill signal CKILL-S4 is activated at a logic “high” level “H” in the fourth slice chip 104, the fourth slice ID SID4<1:0> that is set to have the same binary bit set of “11” as the third slice ID SID3<1:0>. In addition, in the fourth slice chip 104, the fourth corrected slice ID CSID4<1:0> that is set to have a binary bit set of “11” is generated, regardless of the fourth inverted signal INV4<1:0>. The fourth slice chip 104 may be stopped from operating based on the fourth corrected slice ID CSID4<1:0> that is set to have the binary bit set of “11”.

As described above, the memory device 10 is set so that only the first slice chip 101 at the lowest layer and the third slice chip 103, which is at the highest layer and not chip-killed, are operated based on the first to fourth corrected slice IDs CSID1<1:0>, CSID2<1:0>, CSID3<1:0>, and CSID4<1:0>, thereby allowing the memory device 10 to maintain a stable operation even after the chip-kill.

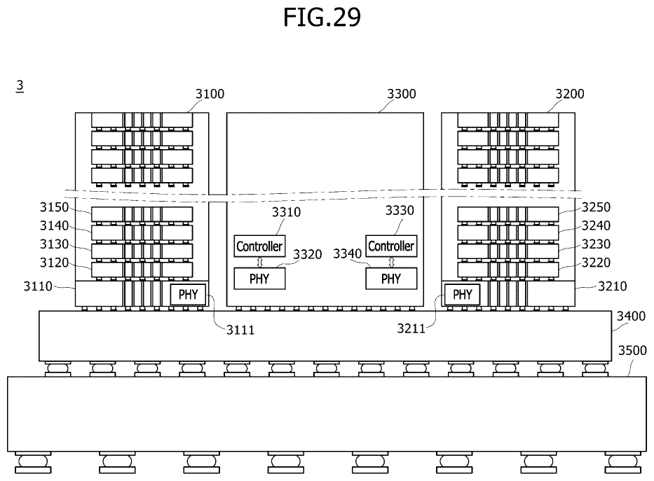

FIG. 29 is a block diagram illustrating a stack memory system 3 according to an embodiment of the present disclosure. As shown in FIG. 29, the stack memory system 3 includes a first stack memory device 3100, a second stack memory device 3200, a processor 3300, an interposer 3400, and a substrate 3500.

The interposer 3400 is disposed over the substrate 3500, and the first stack memory device 3100, the second stack memory device 3200, and the processor 3300 are disposed over the interposer 3400. The processor 3300 is disposed between the first stack memory device 3100 and the second stack device 3200. The interposer 3400 is used to electrically connect the substrate 3500, the first stack memory device 3100, the second stack memory device 3200, and the processor 3300 to each other. Because pitch differences between the first stack memory device 3100, the second stack memory device 3200, and the processor 3300 are large, the first stack memory device 3100, the second stack memory device 3200, and the processor 3300 can be electrically connected to each other using the interposer 3400 including variously formed wirings.

The processor 3300 includes a first controller 3310 that controls the first stack memory device 3100 and a first process interface circuit 3320 that electrically connects the first stack memory device 3100 and the first controller 3310 to each other. The processor 3300 includes a second controller 3330 that controls the second stack memory device 3200 and a second process interface circuit 3340 that electrically connects the second stack memory device 3200 and the second controller 3330 to each other. The processor 3300 provides signals including commands and addresses that control various internal operations of the first stack memory device 3100 through the first process interface circuit 3320 to the first stack memory device 3100 and receives signals from the first stack memory device 3100 through the first process interface circuit 3320. The processor 3300 provides signals including commands and addresses that control various internal operations of the second stack memory device 3200 through the second process interface circuit 3340 to the second stack memory device 3200 and receives signals from the second stack memory device 3200 through the second process interface circuit 3340.

The first stack memory device 3100 includes a first base chip 3110 and first core chips 3120, 3130, 3140, and 3150. The first core chips 3120, 3130, 3140, and 3150 are sequentially stacked over the first base chip 3110 and receive various signals from the first base chip 3110 through through-vias. The first stack memory device 3100 is configured to include four first core chips 3120, 3130, 3140, and 3150 but may be configured to include various numbers of core chips, such as four core chips, eight core chips, or sixteen core chips, depending on the embodiment. The first stack memory device 3100 may be implemented with the memory device 10 as shown in FIG. 1.

The first base chip 3110 includes a first core interface circuit 3111. The first core interface circuit 3111 is configured to be able to communicate with the first process interface circuit 3320 to receive the signals transmitted from the processor 3300 and to apply signals generated from the first core chips 3120, 3130, 3140, and 3150 to the processor 3300.

The second stack memory device 3200 includes a second base chip 3210 and second core chips 3220, 3230, 3240, and 3250. The second core chips 3220, 3230, 3240, and 3250 are sequentially stacked over the second base chip 3210 and receive various signals from the second base chip 3110 through through-vias. The second stack memory device 3200 is configured to include four first core chips 3220, 3230, 3240, and 3250 but may be configured to include various numbers of core chips, such as four core chips, eight core chips, or sixteen core chips, depending on the embodiment. The second stack memory device 3200 may be implemented with the memory device 10 as shown in FIG. 1.

The second base chip 3210 includes a second core interface circuit 3211. The second core interface circuit 3211 is configured to be able to communicate with the second process interface circuit 3330 to receive the signals transmitted from the processor 3300 and to apply signals generated from the second core chips 3220, 3230, 3240, and 3250 to the processor 3300.

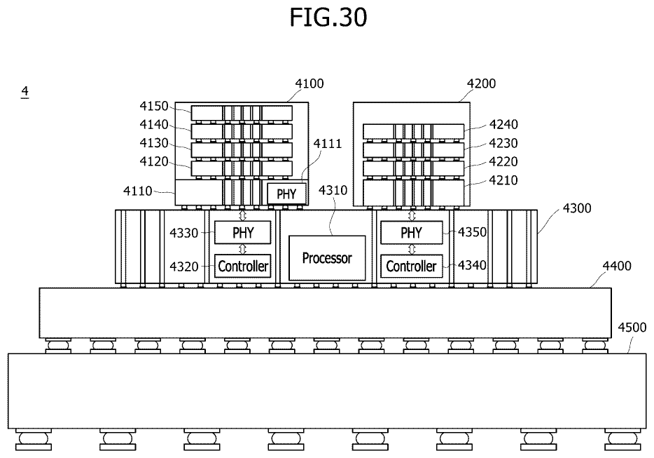

FIG. 30 is a block diagram illustrating a stack memory system 4 according to another embodiment of the present disclosure. As shown in FIG. 30, the stack memory system 4 includes a first stack memory device 4100, a second stack memory device 4200, a system control device 4300, a substrate 4400, and a main board 4500.

The substrate 4400 is disposed over the main board 4500, and the system control device 4300 is disposed over the substrate 4400. The first stack memory device 4100 and the second stack memory device 4200 are disposed over the system control device 4300. The system control device 4300 includes a processor 4310, a first controller 4320, a first process interface circuit 4330, a second controller 4340, and a second process interface circuit 4350.

The processor 4310 is electrically connected to the first controller 4320 that controls various internal operations of the first stack memory device 4100. The processor 4310 provides signals including commands and addresses that control various internal operations of the first stack memory device 4100 to the first stack memory device 4100 through the first process interface circuit 4330 and receives signals from the first stack memory device 4100 through the first process interface circuit 4330. The processor 4310 is electrically connected to the second controller 4340 to control various internal operations of the second stack memory device 4200. The processor 4310 provides signals including commands and addresses that control various internal operations of the second stack memory device 4100 to the second stack memory device 4200 through the second process interface circuit 4350 and receives signals from the second stack memory device 4200 through the second process interface circuit 4350.

The first stack memory device 4100 includes a first base chip 4110 and first core chips 4120, 4130, 4140, and 4150. The first core chips 4120, 4130, 4140, and 4150 are sequentially stacked over the first base chip 4110 and receive various signals from the first base chip 4110 through through-vias. The first stack memory device 4100 is configured to include four first core chips 4120, 4130, 4140, and 4150 but may be configured to include various numbers of core chips, such as four core chips, eight core chips, or sixteen core chips, depending on the embodiment. The first stack memory device 4100 may be implemented with the memory device 10 shown in FIG. 1.

The first base chip 4110 includes a first core interface circuit 4111. The first core interface circuit 4111 is configured to be able to communicate with the first process interface circuit 4330 to receive signals transmitted from the processor 4310 and to apply signals generated from the first core chips 4120, 4130, 4140, and 4150 to the processor 4310.

The second stack memory device 4200 includes second core chips 4210, 4230, 4230, and 4240. The second core chips 4210, 4230, 4230, and 4240 are sequentially stacked and receive various signals through through-vias. The second stack memory device 4200 is configured to include four first core chips 4210, 4230, 4230, and 4240 but may be configured to include various numbers of stacked core chips, such as four core chips, eight core chips, or sixteen core chips, depending on the embodiment. The second stack memory device 4200 may be formed by stacking the core chips without a base chip. The second stack memory device 4200 may be implemented with the memory device 10 as shown in FIG. 1.

The second stack memory device 4200 is configured to be able to communicate with the second process interface circuit 4350 to receive signals transmitted from the processor 4310 and to apply signals generated from the second core chips 4210, 4230, 4230, and 4240 to the processor 4310.

Concepts are disclosed in conjunction with various examples and embodiments. Those skilled in the art will understand that various modifications, additions, and substitutions are possible without departing from the scope and technical concepts of the present disclosure. The embodiments disclosed in the present specification should be considered from an illustrative standpoint and not considered a restrictive standpoint. The scope of the present disclosure is not limited to the descriptions, and all distinctive features within an equivalent scope should be construed as included in the present disclosure. All changes within the meaning and range of equivalency of the claims are included within their scope.

What is claimed is:

1. A memory device comprising:
a plurality of stacked slice chips,
wherein the plurality of slice chips are electrically connected to each other through a plurality of through-vias,
wherein, when one of the plurality of slice chips is chip-killed, an operation of the plurality of slice chips is determined by correcting a slice ID in each of the plurality of slice chips, and
wherein, among the slice chips that are not chip-killed among the plurality of slice chips, a slice chip at a lowest layer and a slice chip at a highest layer are determined to operate.

2. The memory device of claim 1, wherein the slice chip at the lowest layer comprises:
a slice ID generation circuit configured to generate the slice ID from a pre-slice ID based on a chip kill signal; and
a slice ID calibration circuit configured to generate a corrected slice ID from the pre-slice ID based on a down slice signal.

3. The memory device of claim 2, wherein the chip kill signal is deactivated in the slice chip at the lowest layer.

4. The memory device of claim 2, wherein the slice ID generation circuit is configured to:
count an initialized pre-slice ID to generate the slice ID, and
transmit the slice ID to a slice chip stacked over the slice chip at the lowest layer through the through-via.

5. The memory device of claim 2, wherein the slice ID calibration circuit is configured to receive the down slice ID that is activated to generate the pre-slice ID that is set to have the same binary bit set as the pre-slice ID.

6. The memory chip of claim 1, wherein each of the slice chips stacked over the slice chip at the lowest layer comprises:
a slice ID generation circuit configured to generate a second slice ID from a first slice ID based on a chip kill signal; and
a slice ID calibration circuit configured to generate a corrected slice ID from the first slice ID based on the chip kill signal, a synthetic chip kill signal, and a down slice signal.

7. The memory chip of claim 6, wherein the slice ID generation circuit is configured to:
count the first slice ID to generate the second slice ID when the chip kill signal is deactivated, and
generate the second slice ID that is set to have the same binary bit set as the first slice ID when the chip kill signal is activated.

8. The memory chip of claim 7,
wherein the slice ID generation circuit is included in a first slice chip,
wherein a second slice chip is stacked over the first slice chip, and
wherein the slice ID generation circuit is configured to transmit the second slice ID to the slice chip stacked over the first slice chip through the through-via.

9. The memory chip of claim 6, wherein the slice ID calibration circuit is configured to receive the synthetic chip kill signal that is activated when one of the slice chips is chip-killed.

10. The memory chip of claim 6, wherein, when the chip kill signal is activated and the synthetic chip kill signal is deactivated, the slice ID calibration circuit is configured to generate a corrected slice ID that is set to have a preset first binary bit set.

11. The memory chip of claim 10, wherein, when the synthetic chip kill signal is activated and the chip kill signal is deactivated, the slice ID calibration circuit is configured to generate the corrected slice ID that is set to have a preset second binary bit set.

12. A memory device comprising:
a first slice chip;
a second slice chip stacked over the first slice chip;
a third slice chip stacked over the second slice chip; and
a fourth slice chip stacked over the third slice chip,
wherein, when the second slice chip is chip-killed, the first slice chip and the fourth slice chip are configured to operate and the second slice chip and the third slice chip are configured to stop operating.

13. The memory device of claim 12, wherein, when the third slice chip is chip-killed, the first slice chip and the fourth slice chip are configured to operate and the second slice chip and the third slice chip are configured to stop operating.

14. The memory device of claim 12, wherein, when the fourth slice chip is chip-killed, the first slice chip and the third slice chip are configured to operate and the second slice chip and the fourth slice chip are configured to stop operating.

15. The memory device of claim 12, wherein the first slice chip comprises:
a slice ID generation circuit configured to generate a slice ID from a pre-slice ID based on a chip kill signal; and
a slice ID calibration circuit configured to generate a corrected slice ID from the pre-slice ID based on a down slice signal.

16. The memory device of claim 15, wherein the chip kill signal is deactivated in the first slice chip.

17. The memory device of claim 15, wherein the slice ID generation circuit is configured to:
count the pre-slice ID initialized to generate the slice ID, and
transmit the slice ID to the slice chip stacked over the first slice chip through a through-via.

18. The memory device of claim 15, wherein the slice ID calibration circuit is configured to receive the down slice ID that is activated to generate the pre-slice ID that is set to have the same binary bit set as the pre-slice ID.

19. The memory device of claim 12, wherein each of the second slice chip, the third slice chip, and the fourth slice chip comprises:
a slice ID generation circuit configured to generate a second slice ID from a first slice ID based on a chip kill signal; and
a slice ID calibration circuit configured to generate a corrected slice ID from the first slice ID based on the chip kill signal, a synthetic chip kill signal, and a down slice signal.

20. The memory device of claim 19, wherein the slice ID generation circuit is configured to:
count the first slice ID to generate the second slice ID when the chip kill signal is deactivated, and
generate the second slice ID that is set to have the same binary bit set as the first slice ID when the chip kill signal is activated.

21. The memory device of claim 19, wherein, when the chip kill signal is activated and the synthetic chip kill signal is deactivated, the slice ID calibration circuit is configured to generate a corrected slice ID that is set to have a preset first binary bit set.

22. The memory device of claim 19, wherein, when the synthetic chip kill signal is activated and the chip kill signal is deactivated, the slice ID calibration circuit is configured to generate the corrected slice ID that is set to have a preset second binary bit set.
